(19) United States
(12) Patent Application Publication
(10) Pub. No.: US 2005/0037580 A1
(43) Pub. Date: Feb. 17, 2005

(54) Manufacturing method for semiconductor device

(76) Inventors: Kazuaki Nakajima, Kamakura-shi (JP); Kyoichi Suguro, Yokohama-shi (JP)

Correspondence Address: Finnegan, Henderson, Farabow,;Garrett & Dunner, L.L.P., 1300 I Street, N.W., Washington, DC, 20005-3315, US

(21) Appl. No.: 10/887,921

(22) Filed: Jul. 12, 2004

(30) Foreign Application Priority Data
Jul. 25, 2003 (JP) 2003-201693
Nov. 28, 2003 (JP) 2003-400581

(51) Int. Cl. H01L 21/8238

(52) U.S. Cl. 438/275; 438/231

(57) ABSTRACT

Disclosed is a manufacturing method for a semiconductor device comprising forming a structure comprising a first gate insulating film provided in a first region, a first conducting portion provided on the first gate insulating film, a second gate insulating film provided in a second region, and a second conducting portion provided on the second gate insulating film, the first conducting portion and second conducting portion being formed of the same conducting film, a work function of a bottom of the first conducting portion being equal to a work function of a bottom of the second conducting portion, forming a third conducting portion on the second conducting portion by a plating method, and varying the work function of the bottom of the second conducting portion by diffusing a metal element contained in the third conducting portion to the second conducting portion.

### CROSS-REFERENCE TO RELATED APPLICATIONS

This application is based upon and claims the benefit of priority from prior Japanese Patent Applications No. 2003-201693, filed Jul. 25, 2003; and No. 2003-400581, filed Nov. 28, 2003, the entire contents of both of which are incorporated herein by reference.

### BACKGROUND OF THE INVENTION

1. Field of the Invention

The present invention relates to a manufacturing method for a semiconductor device.

2. Description of the Related Art

In recent years, there have been growing demands for an increase in the degree of integration of semiconductor devices and in their operating speeds. To meet these demands, efforts have been made to reduce the sizes of elements and inter-element dimensions and to reduce the resistance of electrodes and wiring. To achieve such a reduction in resistance, proposals have been made for a polycide structure having a metal silicide stacked on polycrystalline silicon and a polymetal structure having metal stacked on polycrystalline silicon. However, a problem with the polycide and polymetal structures is gate depletion in the polycrystalline silicon.

Thus, a structure having a metal film formed directly on a gate insulating film, i.e. what is called a “metal gate structure” is considered to be promising. However, the metal gate structure creates a new problem different from that with the polycide or polymetal structure. For the polycide or polymetal structure, the threshold voltage of a transistor is determined by the concentration of impurities in a channel region and the concentration of impurities in a polycrystalline silicon film. In contrast, for the metal gate structure, the threshold voltage of the transistor is determined by the concentration of impurities in the channel region and the work function of a metal gate electrode. Thus, what is called a“dual metal gate structure” is required which uses two types of gate electrode materials having different work functions for an n type MIS transistor and for a p type MIS transistor. For example, a conductive material with a work function φm of 4.3 eV or less is used for a gate electrode of the n type MIS transistor. A conductive material with a work function φm of 4.8 eV or more is used for a gate electrode of the p type MIS transistor.

As a method of obtaining a dual gate structure, Jpn. Pat. Appln. KOKAI Publication No. 2002-118175 proposes a method of depositing a gate metal film both on the n type MIS transistor region and on the p type MIS transistor region, subsequently removing the gate metal film from one of these regions, and subsequently depositing another gate metal film. However, with this method, the second metal film is deposited on the region from which the gate metal film has been removed. Accordingly, the structure may be severely damaged, degrading the characteristics and reliability of the transistors.

Further, Jpn. Pat. Appln. KOKAI Publication No. 2002-118175 proposes a method of depositing a gate metal film both on the n type MIS transistor region and on the p type MIS transistor region, subsequently implanting ions of metal element with a low work function into the gate metal film in one of the regions, and subsequently carrying out thermal treatment to diffuse the implanted ions of metal element. However, possible damage caused by the ion implantation may degrade the reliability of the gate insulating film or the like. This may degrade the characteristics and reliability of the transistors.

In this manner, the metal gate structures have been proposed in order to reduce the resistance of electrodes and wiring. However, it has hitherto been difficult to adjust the work function of the gate electrode without affecting the characteristics or reliability of the MIS transistors.

### BRIEF SUMMARY OF THE INVENTION

According to a first aspect of the present invention, there is provided a manufacturing method for a semiconductor device comprising a first conduction type MIS transistor provided in a first region and a second conduction type MIS transistor provided in a second region, the method comprising: forming a structure comprising a first gate insulating film provided in the first region, a first conducting portion provided on the first gate insulating film, a second gate insulating film provided in the second region, and a second conducting portion provided on the second gate insulating film, the first conducting portion and second conducting portion being formed of the same conducting film, a work function of a bottom of the first conducting portion being equal to a work function of a bottom of the second conducting portion; forming a third conducting portion on the second conducting portion by a plating method; and varying the work function of the bottom of the second conducting portion by diffusing a metal element contained in the third conducting portion to the second conducting portion.

According to a second aspect of the present invention, there is provided a manufacturing method for a semiconductor device comprising a first conduction type MIS transistor provided in a first region and a second conduction type MIS transistor provided in a second region, the method comprising: forming a structure comprising a first gate insulating film provided in the first region, a first conducting portion provided on the first gate insulating film, a second gate insulating film provided in the second region, and a second conducting portion provided on the second gate insulating film, the first conducting portion and second conducting portion being formed of the same conducting film, a work function of a bottom of the first conducting portion being equal to a work function of a bottom of the second conducting portion; replacing an upper part of the second conducting portion with a third conducting portion by a plating method; and varying the work function of the bottom of the second conducting portion by diffusing a metal element contained in the third conducting portion to a lower part of the second conducting portion.

### BRIEF DESCRIPTION OF THE SEVERAL VIEWS OF THE DRAWING

FIGS. 1A to 1K are sectional views schematically showing a manufacturing method for a semiconductor device according to a first embodiment of the present invention;

FIGS. 2A to 2D are sectional views schematically showing a manufacturing method for a semiconductor device according to a first variation of the first embodiment of the present invention;

FIG. 3 is a sectional view schematically showing a configuration of a semiconductor device according to a second variation of the first embodiment of the present invention;

FIGS. 4A to 4E are sectional views schematically showing a manufacturing method for a semiconductor device according to a second embodiment of the present invention;

FIGS. 5A to 5G are sectional views schematically showing a manufacturing method for a semiconductor device according to a third embodiment of the present invention;

FIGS. 6A to 6E are sectional views schematically showing a manufacturing method for a semiconductor device according to a fourth embodiment of the present invention;

FIGS. 7A to 7D are sectional views schematically showing a manufacturing method for a semiconductor device according to a fifth embodiment of the present invention;

FIGS. 8A to 8G are sectional views schematically showing a manufacturing method for a semiconductor device according to a sixth embodiment of the present invention;

FIGS. 9A and 9B are views illustrating the principle of the manufacturing method for a semiconductor device according to the embodiments of the present invention;

FIGS. 10A and 10B are views illustrating the principle of the manufacturing method for a semiconductor device according to the embodiments of the present invention;

FIGS. 11A and 11B are views illustrating the principle of the manufacturing method for a semiconductor device according to the embodiments of the present invention;

FIGS. 12A and 12B are views illustrating the principle of the manufacturing method for a semiconductor device according to the embodiments of the present invention;

FIG. 13 is a photograph showing the surface of a nonuniform plated film;

FIGS. 14A to 14E are sectional views schematically showing a manufacturing method for a semiconductor device according to a seventh embodiment of the present invention;

FIGS. 15A to 15D are sectional views schematically showing a manufacturing method for a semiconductor device according to an eighth embodiment of the present invention;

FIGS. 16A to 16G are sectional views schematically showing a manufacturing method for a semiconductor device according to a ninth embodiment of the present invention;

FIGS. 17A to 17I are sectional views schematically showing a manufacturing method for a semiconductor device according to a tenth embodiment of the present invention;

FIGS. 18A and 18B are views illustrating the principle of the manufacturing methods for a semiconductor device according to the embodiments of the present invention;

FIG. 19 is a graph showing the relationship between implanted ion amount and coverage ratio;

FIGS. 20A to 20E are sectional views schematically showing a manufacturing method for a semiconductor device according to an eleventh embodiment of the present invention;

FIGS. 21A to 21C are sectional views schematically showing a manufacturing method for a semiconductor device according to a variation of the eleventh embodiment of the present invention; and

FIGS. 22A to 22C are sectional views schematically showing a manufacturing method for a semiconductor device according to a twelfth embodiment of the present invention.

### DETAILED DESCRIPTION OF THE INVENTION

Embodiments of the present invention will be described with reference to the drawings.

(Embodiment 1)

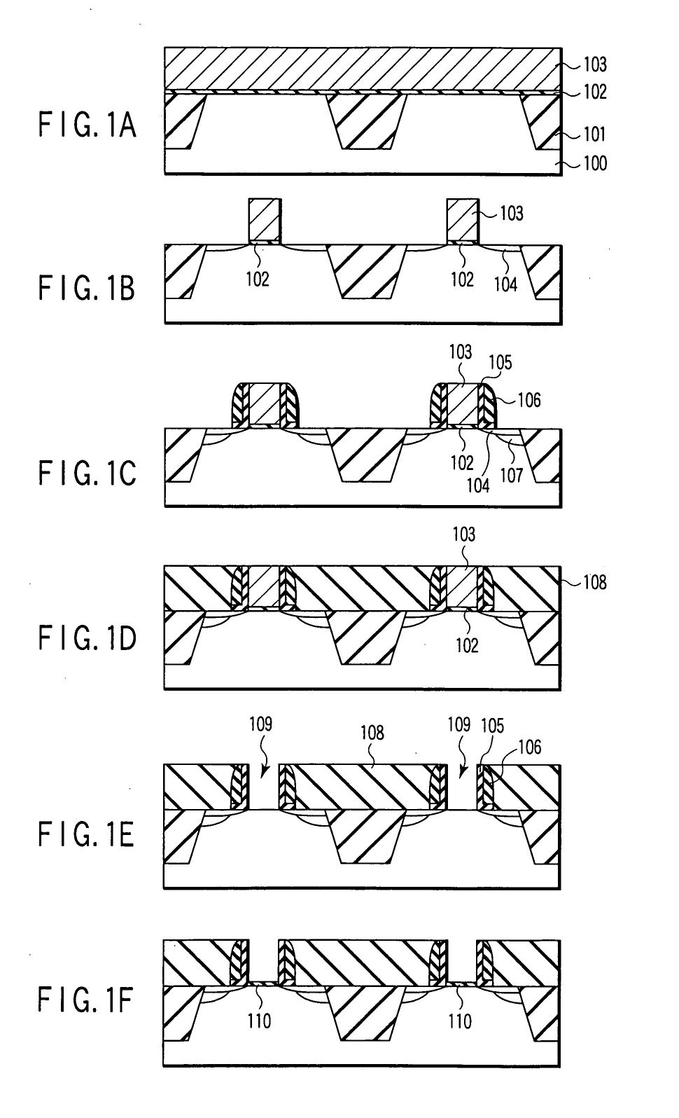

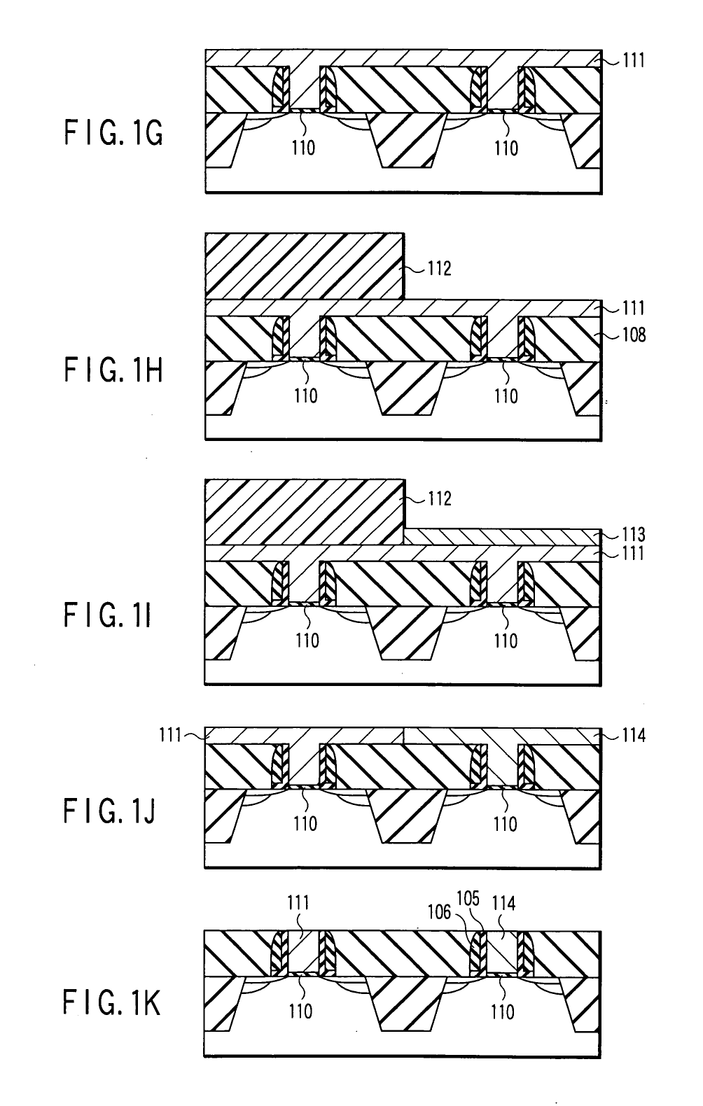

FIGS. 1A to 1K are sectional views schematically showing a manufacturing method for a semiconductor device according to a first embodiment of the present invention.

First, as shown in FIG. 1A, a silicon oxide film 102 is formed on a single-crystal silicon substrate (semiconductor substrate) 100 having an isolation region 101. Subsequently, a polycrystalline silicon film 103 is deposited on the silicon oxide film.

Then, as shown in FIG. 1B, the polycrystalline silicon film 103 is patterned by anisotropic etching to form dummy gate electrodes. Subsequently, As⁺ ions are implanted into a region in which an n type MIS transistor is to be formed (this region will hereinafter be referred to as an “n type MIS region”). B⁺ ions are implanted into a region in which a p type MIS transistor is to be formed (this region will hereinafter be referred to as a “p type MIS region”). Furthermore, thermal treatment at 800° C. is carried out for five seconds to form a diffusion layer 104 as a part of a source and drain area.

Then, as shown in FIG. 1C, a silicon nitride film 105 and a silicon oxide film 106 are deposited all over the surface of the structure. Subsequently, an etchback operation is performed to leave the silicon nitride film 105 and the silicon oxide film 106 on side walls of the dummy gate electrodes. Subsequently, P⁺ ions are implanted into the n type MIS region. B⁺ ions are implanted into the p type MIS region. Furthermore, thermal treatment at 800° C. is carried out for five seconds to form a diffusion layer 107 as a part of the source and drain area.

Then, as shown in FIG. 1D, an interlayer insulating film 108 is deposited all over the surface of the structure. Subsequently, the interlayer insulating film 108 is flattened by chemical mechanical polishing (CMP) to expose a surface of the polycrystalline silicon film 103.

Then, as shown in FIG. 1E, the polycrystalline silicon film 103 is removed, and the silicon oxide film 102 is removed. Thus, grooves 109 are formed each of which is surrounded by the silicon substrate 100 and the silicon nitride film 105. Subsequently, In⁺ ions are implanted into the n type MIS region. As⁺ ions are implanted into the p type MIS region. Furthermore, the structure is heated at 1,000° C. for a short time. This allows the adjustment of the concentration of impurities in a channel region to adjust the threshold voltages of an n type MIS transistor and a p type MIS transistor.

Then, as shown in FIG. 1F, a plasma oxinitride process is used to form a thin silicon oxinitride film at the bottom of each of the grooves 109 as a gate insulating film 110.

Then, as shown in FIG. 1G, a CVD process is used to deposit a tungsten silicide film (hereinafter referred to as a “WSiP film”) 111 containing phosphorus (P), all over the surface of the structure. The WSiP film 111 has a work function of 4.3 eV or less. For example, W(CO)₆, SiH₄, and PH₃ are used as a source gas. When the W silicide film contains P, the work function can be reduced compared to a W silicide film not containing any P.

Then, as shown in FIG. 1H, the n type MIS region is covered with a photo resist film 112. Specifically, the photo resist film 112 is formed, as a protecting portion, on the WSiP film (first conducting portion) formed in the n type MIS region. A structure free from the photo resist film 112 is formed on the WSiP film (second conducting portion) formed in the p type MIS region.

Then, as shown in FIG. 1I, an electroplating process is used to form a Pt film 113 (third conducting portion) on that part of the. WSiP film 111 which is not covered with the photo resist film 112. The Pt film 113 has a work function of about 5.0 eV. Pt(NH₃)₂(NO₂)₂ is used as a plating solution. The temperature of a plating tank is 60 to 80° C. The plating solution has a pH of 1 to 4 and a current density of 0.2 to 4 A/cm².

If the Pt film is formed using the CVD or PVD process without using the plating process, the Pt film is also formed on an organic material film such as the photo resist film. However, few organic materials can withstand a high temperature of 200° C. or higher and plasma damage. Further, the photo resist film and the Pt film do not adhere properly to each other and are likely to be released.

Further, it is contemplated that after the Pt film has been formed all over the WSiP film, the photo resist film may be formed in the n type MIS region, and the Pt film may be removed from the p type MIS region by dry etching. However, a halide of noble metal such as the Pt film has a low vapor pressure and is thus difficult to dry etch. It is thus difficult to form such a halide into fine patterns.

According to the present embodiment, the use of the plating process enables the Pt film to be formed only in a conductive region, i.e. only in the exposed region of the WSiP film. Further, the Pt film can be formed at a temperature lower than 200° C. and without the need for exposure to plasma. Consequently, the above problems can be avoided.

Then, as shown in FIG. 1J, after the photo resist film 112 has been removed, the structure is heated at about 500° C. This allows the Pt in the Pt film 113 to diffuse to the bottom of the WSiP film 111. That is, the Pt diffuses to the vicinity of the interface between the WSiP film 111 and the gate insulating film 110. As a result, a film (PtWSiP film 114) containing Pt, W, Si, and P is formed in the p type MIS region. Further, the Pt film 113 and the WSiP film 111 react thermally with each other to suck the Si from the WSiP film 111. This serves to reduce the amount of Si contained in the PtWSiP film 114. The W and the Pt film 113 both have high work functions: the W has a work function of about 4.9 eV, and the Pt film has a work function of about 5.0 eV. Therefore, at least the bottom of the PtWSiP film 114 (at least the vicinity of the interface between the PtWSiP film 114 and the gate insulating film 110) has a work function of about 4.8 eV or more.

Then, as shown in FIG. 1K, the CMP process is used to remove those parts of the WSiP film 111 and PtWSiP film 114 which are located outside the grooves. Thus, a gate electrode of the WSiP film 111 is formed in the n type MIS region. A gate electrode of the PtWSiP film 114 is formed in the p type MIS region.

Thus, a CMOS transistor is obtained in which the gate electrode of the n type MIS transistor is composed of the WSiP film 111, having a low work function, and in which the gate electrode of the p type MIS transistor is composed of the PtWSiP film 114, having a higher work function than the WSiP film.

As described above, according to the present embodiment, by using the photo resist film to protect the WSiP film (first conducting portion) formed in the n type MIS region and executing the plating process, the Pt film (third conducting portion) can be selectively formed on the WSiP film (second conducting portion) formed in the p type MIS region. Further, the use of the plating process enables the Pt films to be formed at a low temperature without adversely affecting the photo resist film. Consequently, the Pt film can be formed without adversely affecting the already formed structure. Then, by diffusing the Pt atoms in the Pt film thus obtained to the WSiP film, the work function of the gate electrode in the p type MIS region can be increased. This provides a semiconductor device of a dual metal gate structure which has excellent characteristics and reliability.

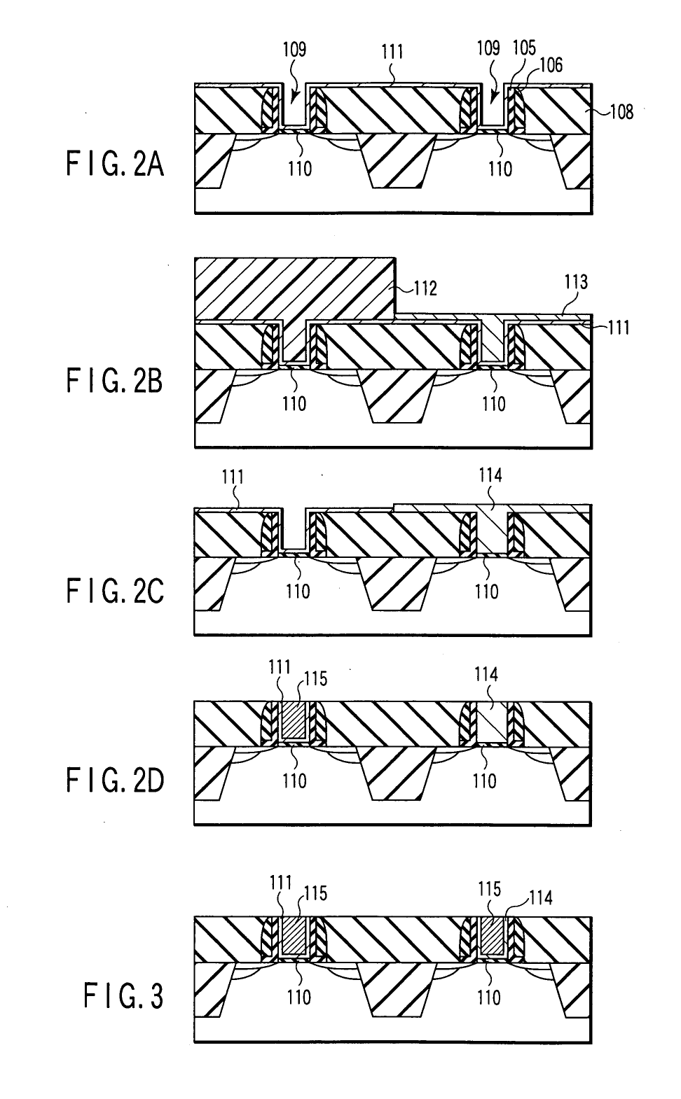

FIGS. 2A to 2D are sectional views schematically showing a manufacturing method for a semiconductor device according to a first variation of the first embodiment of the present invention. Those components of this embodiment which correspond to the above embodiment are denoted by the same reference numerals. Their detailed description is thus omitted.

First, the steps from FIGS. 1A to 1F are executed as in the case with the above embodiment.

Then, as shown in FIG. 2A, the WSiP film 111 is formed on the gate insulating film 110 and interlayer insulating film 108 by the CVD process. However, the WSiP film 111 is formed to be thin along each groove 109 so as not to fill up the grooves 109 completely.

Then, as shown in FIG. 2B, the n type MIS region is covered with the photo resist film 112. Specifically, the photo resist film 112 is formed, as a protecting portion, on the WSiP film formed in the n type MIS region. A structure free from the photo resist film 112 is formed on the WSiP film formed in the p type MIS region. Then, an electroplating process is used to form the Pt film 113 on that part of the WSiP film 111 which is not covered with the photo resist film 112. The plating conditions used are similar to those used in the above embodiment.

Then, as shown in FIG. 2C, the photo resist 112 is removed, and then the structure is heated at a temperature of about 500° C. Thus, as in the case with the above embodiment, the PtWSiP film 114, having a work function of about 4.8 eV or more, is formed in the p type MIS region. In the present variation, the WSiP film 111 is formed to be thin to allow the Pt to diffuse easily to the vicinity of the gate insulating film.

Then, as shown in FIG. 2D, a highly conductive metal film (Al film, Cu film, Ag film, or the like) is deposited all over the surface of the structure. Furthermore, the CMP process is used to remove those parts of the WSiP film 111, PtWSiP film 114, and highly conductive metal film 115 which are located outside the grooves. Thus, a gate electrode formed of a stacked film of the WSiP film 111 and highly conductive metal film 115 is formed in the n type MIS region. A gate electrode formed of the PtWSiP film 114 is formed in the p type MIS region.

FIG. 3 is a sectional view schematically showing a configuration of a semiconductor device according to a second variation of the first embodiment of the present invention.

In the above first variation, in the step in FIG. 2B, the groove 109 in the p type MIS region is completely filled up with the Pt film 113. However, the Pt film 113 may be formed to be thin so as not to fill up the groove 109 completely. In this case, a gate electrode formed of a stacked film of the WSiP film 111 and highly conductive metal film 115 is formed in the n type MIS region. A gate electrode formed of a stacked film of the PtWSiP film 114 and highly conductive metal film 115 is formed in the p type MIS region. It is thus possible to reduce the resistance of the gate electrodes together with the n type MIS transistor and the p type MIS transistor.

(Embodiment 2)

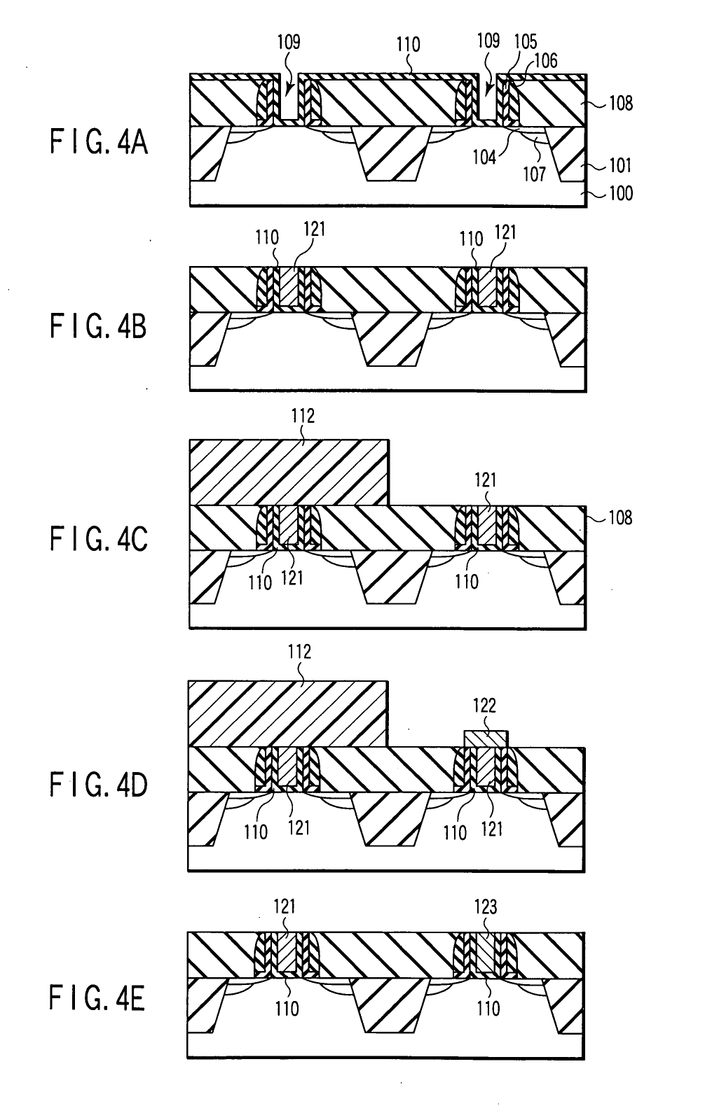

FIGS. 4A to 4E are sectional views schematically showing a manufacturing method for a semiconductor device according to a second embodiment of the present invention. Those components of this embodiment which correspond to the first embodiment are denoted by the same reference numerals. Their detailed description is thus omitted.

First, the steps from FIGS. 1A to 1E are executed as in the case with the above embodiment.

Then, as shown in FIG. 4A, an HfO₂ film as the gate insulating film 110 is formed by the CVD process.

Then, as shown in FIG. 4B, a TaN film 121 as a conducting film is deposited all over the surface of the structure by the CVD process. The TaN film has a work function of 4.3 eV or less. Subsequently, the CMP process is used to remove those parts of the gate insulating film 110 and TaN film 121 which are located outside the grooves.

Then, as shown in FIG. 4C, the n type MIS region is covered with the photo resist film 112. Specifically, the photo resist film 112 is formed, as a protecting portion, on the TaN film 121 (first conducting portion) formed in the n type MIS region. A structure free from the photo resist film 112 is formed on the TaN film 121 (second conducting portion) formed in the p type MIS region.

Then, as shown in FIG. 4D, an electroless plating process is used to form a Pd film 122 (third conducting portion) on the that part of the TaN film 121 which is not covered with the photo resist film 112. The Pd film 122 has a work function of about 5.0 eV. PdSO₄ is used as a plating solution. The temperature of the plating tank is 60 to 80° C. The plating solution has a pH of 1 to 4. Thus, the use of the plating process enables the Pd film 122 to be formed only in a conductive region, i.e. only in the exposed region of the TaN film 121. Further, the Pd film can be formed at a temperature low enough to avoid adversely affecting the photo resist film 112.

Then, as shown in FIG. 4E, after the photo resist film 112 has been removed, the structure is heated at about 500° C. This allows the Pd in the Pd film 122 to diffuse to the bottom of the TaN film 121. That is, the Pd diffuses to the vicinity of the interface between the TaN film 121 and the gate insulating film 110. As a result, a TaN film 123 containing Pd is formed in the p type MIS region. Therefore, at least the bottom of the TaN film 123 containing Pd (at least the vicinity of the interface between the TaN film 123 containing Pd and the gate insulating film 110) has a work function of about 4.8 eV or more. Subsequently, the CMP process is used to flatten the surface of the structure. A gate electrode formed of the TaN film 121 is formed in the n type MIS region. A gate electrode formed of TaN film 123 containing Pd is formed in the p type MIS region.

Thus, a CMOS transistor is obtained in which the n type MIS transistor has a gate electrode having a low work function, and in which the p type MIS transistor has a gate electrode having a high work function.

In forming the Pd film by electroless plating, a Pd film containing B may be formed using as a reducing agent a boron compound such as dimethylammineboron (DMAB:(CH₃)₂NHBH₃). In this case, the B, having a work function of 4.8 eV or more, can be diffused to the vicinity of the gate insulating film simultaneously with the Pd. It is thus possible to increase the work function of the gate electrode of the p type MIS transistor.

As described above, in the present embodiment, a semiconductor device of a dual metal gate structure which has excellent characteristics and reliability is obtained by diffusing the metal elements from the upper conducting portion (third conducting portion), formed by the plating process, to the lower conducting portion (second conducting portion), as in the case with the first embodiment.

(Embodiment 3)

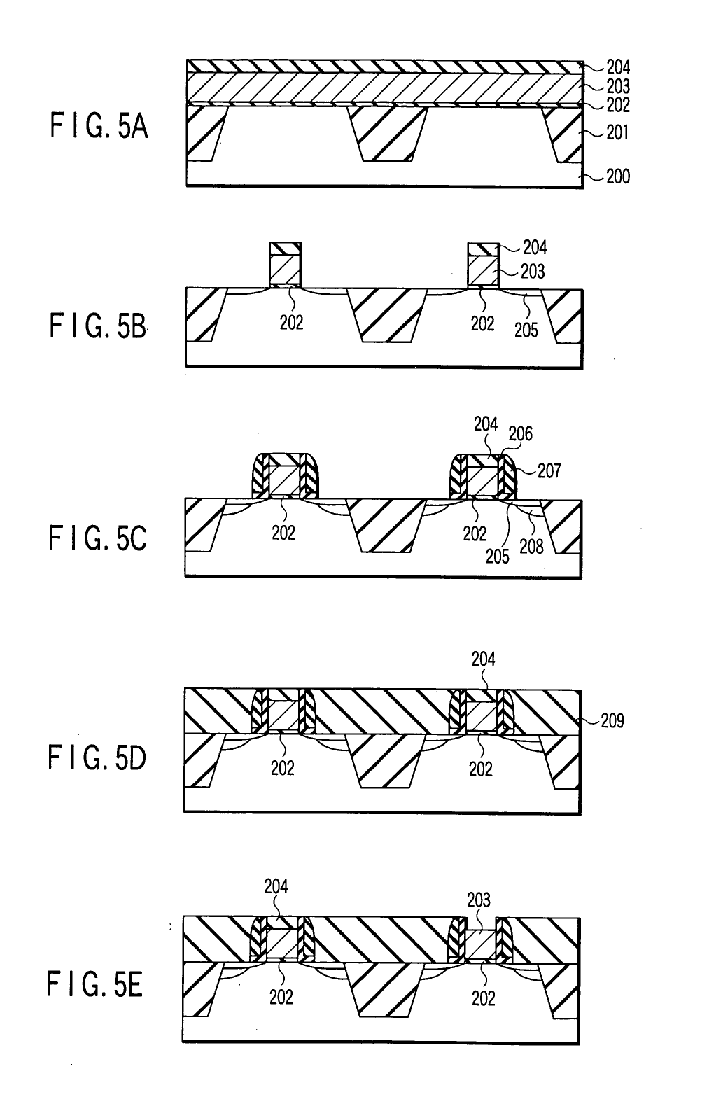

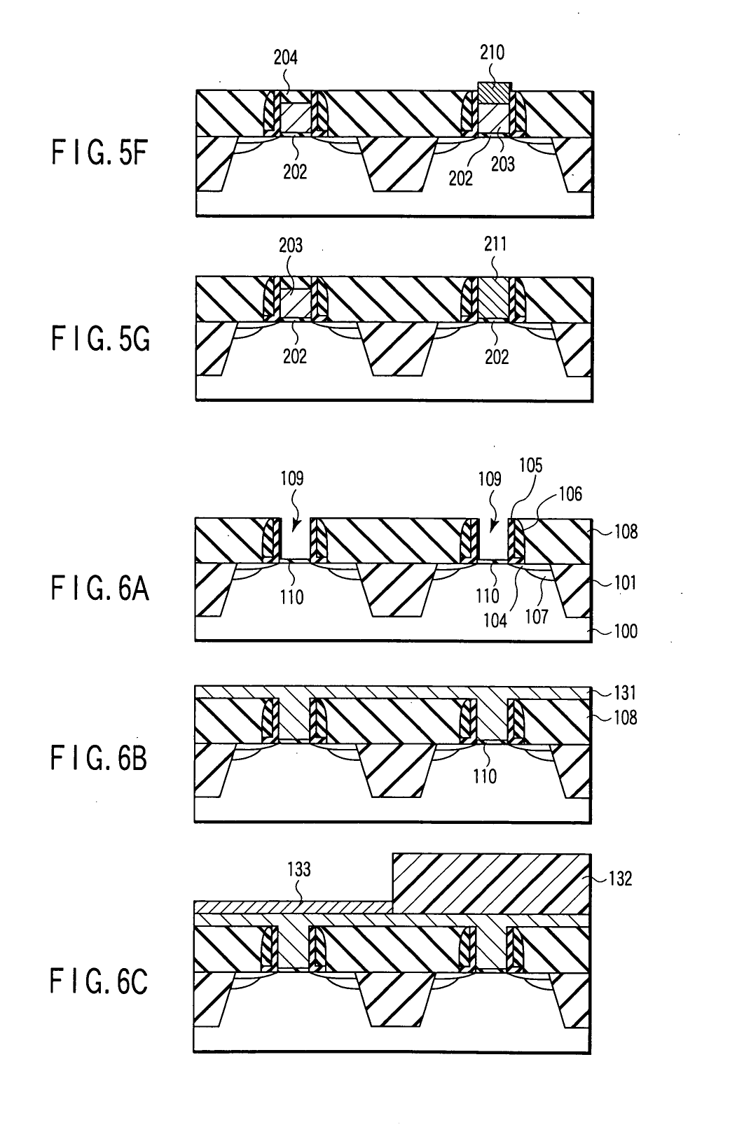

FIGS. 5A to 5G are sectional views schematically showing a manufacturing method for a semiconductor device according to a third embodiment of the present invention.

First, as shown in FIG. 5A, a gate insulating film 202 is formed on a single-crystal silicon substrate (semiconductor substrate) 200 having an isolation region 201. Subsequently, a WSi film 203 is deposited on the gate insulting film 202 by the CVD process. The WSi film 203 has a work function of 4.3 eV or less. WF₆ and SiH₄ are used as a source gas. Furthermore, a silicon nitride film 204 is formed on the WSi film 203 by the CVD process.

Then, as shown in FIG. 5B, the silicon nitride film 204 and the WSi film 203 are patterned by anisotropic etching to form electrode structures. Subsequently, As⁺ ions are implanted into the n type MIS region. B⁺ ions are implanted into the p type MIS region. Furthermore, thermal treatment at 800° C. is carried out for five seconds to form a diffusion layer 205 as a part of a source and drain area.

Then, as shown in FIG. 5C, a silicon oxide film 206 and a silicon nitride film 207 are deposited. Subsequently, an etchback operation is performed to leave the silicon nitride film 206 and the silicon oxide film 207 on side walls of the electrode structures. Subsequently, P⁺ ions are implanted into the n type MIS region. B⁺ ions are implanted into the p type MIS region. Furthermore, thermal treatment at 900° C. is carried out for five seconds to form a diffusion layer 208 as a part of the source and drain area.

Then, as shown in FIG. 5D, an interlayer insulating film 209 is deposited all over the surface of the resultant structure. Subsequently, the interlayer insulating film 209 is flattened by chemical mechanical polishing (CMP) to expose a surface of the silicon nitride film 204.

Then, as shown in FIG. 5E, the silicon nitride film 204 is removed from the p type MIS region. Thus, the silicon nitride film 204 is formed, as a protecting portion, on the WSi film (first conducting portion) 203 formed in the n type MIS region. A structure free from the silicon nitride film 204 is formed on the WSi film 203 (second conducting portion) formed in the p type MIS region.

Then, as shown in FIG. 5F, the electroless plating process is used to form an Ni film 210 (third conducting portion) on that part of the WSi film 203 which is not covered with the silicon nitride film 204. The Ni film 210 has a work function of about 4.8 eV or more. NiSO₄ is used as a plating solution. The temperature of the plating tank is 60 to 80° C. The plating solution has a pH of 5 to 10. Thus, the use of the plating process enables the Ni film 210 to be formed only in a conductive region, i.e. only in the exposed region of the WSi film 203.

Then, as shown in FIG. 5G, the resultant structure is heated at about 500° C. This allows the Ni in the Ni film 210 to diffuse to the bottom of the WSi film 203. That is, the Ni diffuses to the vicinity of the interface between the WSi film 203 and the gate insulating film 202. As a result, a WSi film 211 containing Ni is formed in the p type MIS region. Therefore, at least the bottom of the WSi film 211 containing Ni (at least the vicinity of the interface between the WSi film 211 containing Ni and the gate insulating film 202) has a work function of about 4.8 eV or more. Subsequently, the CMP process is used to flatten the surface of the structure. Thus, a gate electrode formed of the WSi film 203 is formed in the n type MIS region. A gate electrode formed of the WSi film 211 containing Ni is formed in the p type MIS region.

Thus, a CMOS transistor is obtained in which the n type MIS transistor has a gate electrode having a low work function, and in which the p type MIS transistor has a gate electrode having a high work function.

As described above, also in the present embodiment, a semiconductor device of a dual metal gate structure which has excellent characteristics and reliability is obtained by diffusing the metal elements from the upper conducting portion, formed by the plating process, to the lower conducting portion, as in the case with the first embodiment.

(Embodiment 4)

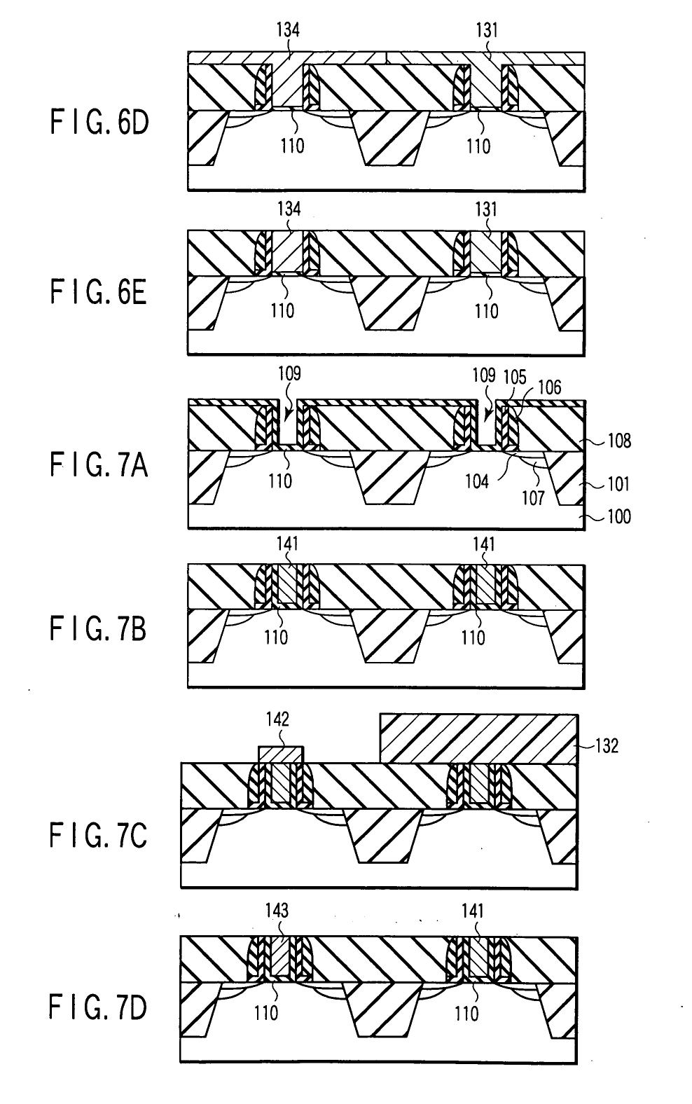

FIGS. 6A to 6E are sectional views schematically showing a manufacturing method for a semiconductor device according to a fourth embodiment of the present invention. Those components of this embodiment which correspond to the first embodiment are denoted by the same reference numerals. Their detailed description is thus omitted.

First, the steps from FIGS. 1A to 1E are executed as in the case with the first embodiment.

Then, as shown in FIG. 6A, the plasma oxinitride process is used to form a thin silicon oxinitride film at the bottom of each of the grooves 109 as the gate insulating film 110.

Then, as shown in FIG. 6B, a W film 131 as a conducting film is deposited all over the surface of the structure by the CVD process. The W film has a work function of 4.8 eV or more.

Then, as shown in FIG. 6C, the p type MIS region is covered with a photo resist film 132. Specifically, the photo resist film 132 is formed, as a protecting portion, on the W film 131 (first conducting portion) formed in the p type MIS region. A structure free from the photo resist film 132 is formed on the W film 131 (second conducting portion) formed in the n type MIS region.

Then, the electroless plating process is used to form an In film 133 (third conducting portion) on the that part of the W film 131 which is not covered with the photo resist film 132. The In film 133 has a work function of about 4.1 eV. In₂(SO₄)₃ is used as a plating solution. The temperature of the plating tank is 60 to 80° C. The plating solution has a pH of 8 to 9. Thus, the use of the plating process enables the In film 133 to be formed only in a conductive region, i.e. only in the exposed region of the W film 131. Further, the In film 133 can be formed at a temperature low enough to avoid adversely affecting the photo resist film 132.

Then, as shown in FIG. 6D, after the photo resist film 132 has been removed, the structure is heated at about 500° C. This allows the In in the In film 133 to diffuse to the bottom of the W film 131. That is, the In diffuses to the vicinity of the interface between the W film 134 and the gate insulating film 110. As a result, a W film 134 containing In is formed in the n type MIS region. Therefore, at least the bottom of the W film 134 containing In (at least the vicinity of the interface between the W film 134 containing In and the gate insulating film 110) has a work function of about 4.3 eV or less.

Subsequently, as shown in FIG. 6E, the CMP process is used to flatten the surface of the structure. A gate electrode formed of the W film 131 is formed in the p type MIS region. A gate electrode formed of W film 134 containing In is formed in the n type MIS region.

Thus, a CMOS transistor is obtained in which the n type MIS transistor has a gate electrode having a low work function, and in which the p type MIS transistor has a gate electrode having a high work function.

As described above, in the present embodiment, a semiconductor device of a dual metal gate structure which has excellent characteristics and reliability is obtained by diffusing the metal elements from the upper conducting portion, formed by the plating process, to the lower conducting portion, as in the case with the first embodiment.

In forming the In film by electroless plating, an In film containing P may be formed using a phosphorous compound as a reducing agent. In this case, the P, having a work function of 3.8 eV or less, can be diffused to the vicinity of the gate insulating film simultaneously with the In. It is thus possible to reduce the work function of the gate electrode of the n type MIS transistor.

Further, in the present embodiment, structures similar to those in the first and second variations of the first embodiment can be employed by reversing the conduction types (p and n types).

(Embodiment 5)

FIGS. 7A to 7D are sectional views schematically showing a manufacturing method for a semiconductor device according to a fifth embodiment of the present invention. Those components of this embodiment which correspond to the first embodiment are denoted by the same reference numerals. Their detailed description is thus omitted.

First, the steps from FIGS. 1A to 1E are executed as in the case with the first embodiment.

Then, as shown in FIG. 7A, an La₂O₃ film is formed as the gate insulating film 110 by the CVD process.

Then, as shown in FIG. 7B, an Mo film 141 as a conducting film is deposited all over the surface of the structure by the CVD process. The Mo film 141 has a work function of 4.8 eV or more. Subsequently, the CMP process is used to remove those parts of the gate insulating film 110 and Mo film 141 which are located outside the grooves.

Then, as shown in FIG. 7C, the p type MIS region is covered with the photo resist film 132. Specifically, the photo resist film 132 is formed, as a protecting portion, on the Mo film 141 (first conducting portion) formed in the p type MIS region. A structure free from the photo resist film 132 is formed on the Mo film 141 (second conducting portion) formed in the n type MIS region.

Then, the electroplating process is used to form a Tl film 142 (third conducting portion) on the that part of the Mo film 141 which is not covered with the photo resist film 132. The Tl film 142 has a work function of about 3.8 eV. TlCl₂ is used as a plating solution. Thus, the use of the plating process enables the Tl film 142 to be formed only in a conductive region, i.e. only in the exposed region of the Mo film 141. Further, the Tl film 142 can be formed at a temperature low enough to avoid adversely affecting the photo resist film 132.

Then, as shown in FIG. 7D, after the photo resist film 132 has been removed, the structure is heated at about 500° C. This allows the Tl in the Tl film 142 to diffuse to the bottom of the Mo film 141. That is, the Tl diffuses to the vicinity of the interface between the Mo film 141 and the gate insulating film 110. As a result, a Mo film 143 containing Tl is formed in the n type MIS region. Therefore, at least the bottom of the Mo film 143 containing Tl (at least the vicinity of the interface between the Mo film 143 containing Tl and the gate insulating film 110) has a work function of about 4.3 eV or less. Subsequently, the CMP process is used to flatten the surface of the structure. Thus, a gate electrode formed of the Mo film 141 is formed in the p type MIS region. A gate electrode formed of Mo film 143 containing Tl is formed in the n type MIS region.

Thus, a CMOS transistor is obtained in which the n type MIS transistor has a gate electrode having a low work function, and in which the p type MIS transistor has a gate electrode having a high work function.

As described above, in the present embodiment, a semiconductor device of a dual metal gate structure which has excellent characteristics and reliability is obtained by diffusing the metal elements from the upper conducting portion, formed by the plating process, to the lower conducting portion, as in the case with the first embodiment.

(Embodiment 6)

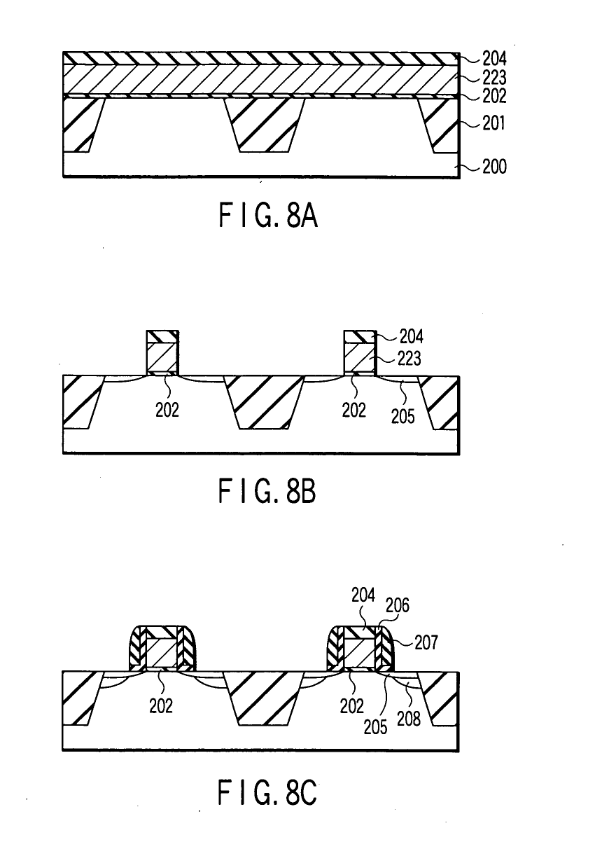

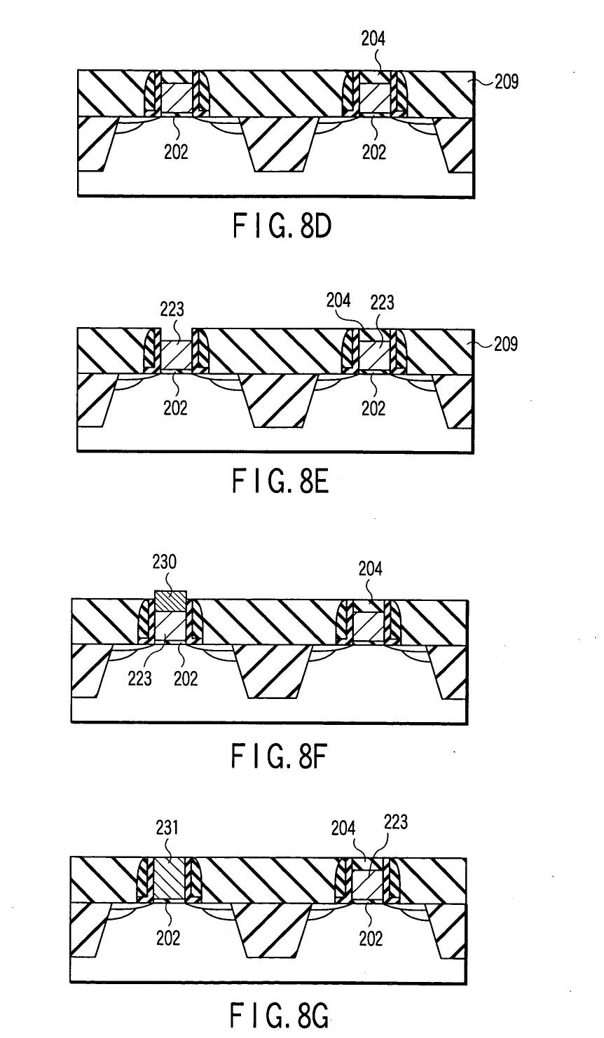

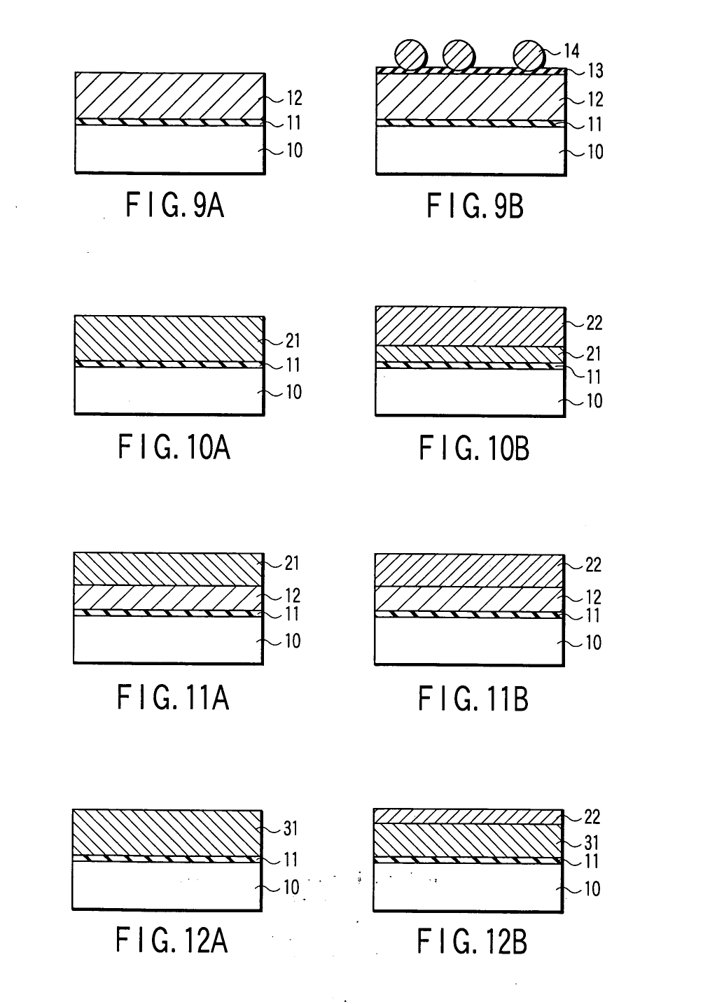

FIGS. 8A to 8G are sectional views schematically showing a manufacturing method for a semiconductor device according to a sixth embodiment of the present invention.

First, as shown in FIG. 8A, the gate insulating film 202 is formed on the single-crystal silicon substrate (semiconductor substrate) 200 having the isolation region 201. Subsequently, a W film 223 is deposited on the gate insulting film 202 by the CVD process. The W film 223 has a work function of 4.8 eV or more. WF₆ and H₂ are used as a source gas. Furthermore, the silicon nitride film 204 is formed on the W film 223 by the CVD process.

Then, as shown in FIG. 8B, the silicon nitride film 204 and the W film 223 are patterned by anisotropic etching to form electrode structures. Subsequently, As⁺ ions are implanted into the n type MIS region. B⁺ ions are implanted into the p type MIS region. Furthermore, thermal treatment at 1,000° C. is carried out for five seconds to form the diffusion layer 205 as a part of a source and drain area.

Then, as shown in FIG. 8C, the silicon oxide film 206 and the silicon nitride film 207 are deposited. Subsequently, an etchback operation is performed to leave the silicon nitride film 206 and the silicon oxide film 207 on side walls of the electrode structures. Subsequently, P⁺ ions are implanted into the n type MIS region. B⁺ ions are implanted into the p type MIS region. Furthermore, thermal treatment at 950° C. is carried out for 10 seconds to form the diffusion layer 208 as a part of the source and drain area.

Then, as shown in FIG. 8D, the interlayer insulating film 209 is deposited all over the surface of the resultant structure. Subsequently, the interlayer insulating film 209 is flattened by the chemical mechanical polishing (CMP) to expose the surface of the silicon nitride film 204.

Then, as shown in FIG. 8E, the silicon nitride film 204 is removed from the n type MIS region. The silicon nitride film 204 is formed, as a protecting portion, on the W film (first conducting portion) 223 formed in the p type MIS region. A structure free from the silicon nitride film 204 is formed on the W film 223 (second conducting portion) formed in the n type MIS region.

Then, as shown in FIG. 8F, the electroless plating process is used to form an In film 230 (third conducting portion) on that part of the W film 223 which is not covered with the silicon nitride film 204. The In film 230 has a work function of about 4.3 eV or less. InCl₂ is used as a plating solution. Thus, the use of the plating process enables the In film 230 to be formed only in a conductive region, i.e. only in the exposed region of the W film 223.

Then, as shown in FIG. 8G, the resultant structure is heated at about 500° C. This allows the In in the In film 230 to diffuse to the bottom of the W film 223. That is, the In diffuses to the vicinity of the interface between the W film 223 and the gate insulating film 202. As a result, a W film 231 containing In is formed in the n type MIS region. Therefore, at least the bottom of the W film 231 containing In (at least the vicinity of the interface between the W film 231 containing In and the gate insulating film 202) has a work function of about 4.3 eV or less. Subsequently, the CMP process is used to flatten the surface of the structure. Thus, a gate electrode formed of the W film 223 is formed in the p type MIS region. A gate electrode formed of W film 231 containing In is formed in the n type MIS region.

Thus, a CMOS transistor is obtained in which the n type MIS transistor has a gate electrode having a low work function, and in which the p type MIS transistor has a gate electrode having a high work function.

As described above, also in the present embodiment, a semiconductor device of a dual metal gate structure which has excellent characteristics and reliability is obtained by diffusing the metal elements from the upper conducting portion, formed by the plating process, to the lower conducting portion, as in the case with the first embodiment.

(Embodiment 7)

The principle of the present embodiment will be described with reference to FIGS. 9A and 9B to 12A and 12B.

First, as shown in FIG. 9A, the gate insulating film 11 of thickness 2.5 nm was formed on the silicon substrate 10. Subsequently, the WSi film 12 of thickness 50 nm was formed by the CVD process.

Then, a Pd film was formed on the WSi film 12 by the electroless plating process by using PdSO₄ as a plating solution and setting the temperature of the plating tank at 60 to 80° C. and the pH of the plating solution at 1 to 4.

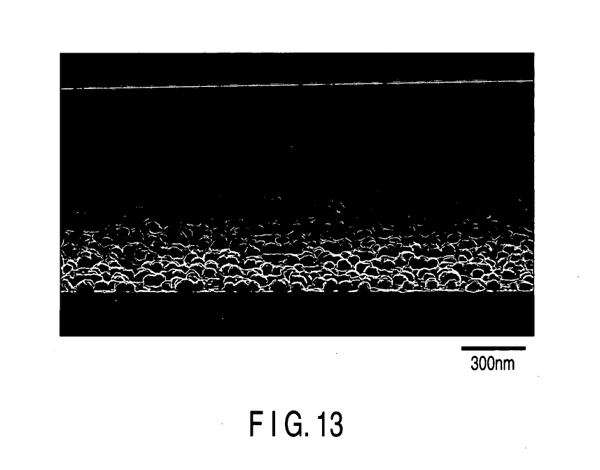

After the Pd film had been formed on the WSi film, the conditions of the surface of the resultant structure were observed. It was then found that there are some cases where a conformal Pd film had not been formed on the surface of the WSi film and Pd had precipitated granularly, as shown in FIG. 13. The interface between the Pd crystal grains and the WSi film was analyzed. It was then found that no silicon oxide films were present in the area between the Pd crystal grains and the WSi film, whereas a silicon oxide film had been formed on the surface of the WSi film. This is assumed to be because the silicon in the WSi was oxidized in the plating solution.

For plating, electrons must be moved between a plating material and a material to be plated. When a silicon oxide film is formed on the surface of the WSi film, such movement of electros is hindered. On the other hand, Pd grains are formed on the surface of the WSi film before the silicon oxide film is formed, the surfaces of the Pd grains are not covered with the silicon oxide film. Accordingly, the Pd in the plating solution adheres more easily to Pd cores, which are initially formed, than to the surface of the WSi film, covered with the silicon oxide film. As a result, as shown in FIG. 9B, large Pd crystal grains 14 are finally formed. Thus, almost no Pd films are formed in the area in which the silicon oxide film 13 is formed.

Now, the examples shown in FIGS. 10A and 10B will be described.

First, as shown in FIG. 10A, the gate insulating film 11 of thickness 2.5 nm was formed on the silicon substrate 10. Subsequently, the W film 21 of thickness 50 nm was formed by the CVD process.

Then, as shown in FIG. 10B, the Pd film 22 was formed by the electroless plating process by using PdSO₄ as a plating solution and setting the temperature of the plating tank at 60 to 80° C. and the pH of the plating solution had at 1 to 4. In this case, no oxide films were formed on the surface of the W film 21. This is because the W film 21 does not contain any silicon and because tungsten oxides are dissolved in a plating solution. As a result, the substitution (replacement) reaction between Pd and W is facilitated to form a conformal Pd film 22.

It has thus been found that a stable oxide film may be formed on the surface of a film to be plated in a plating solution and that in such a case, non-uniform plated film is formed. Such a phenomenon occurs not only with WSi but also with TaN and NbN. In this case, a tantalum oxide film or a niobium oxide film is formed. This stable oxide film hinders the formation of a uniform plated film. Further, this phenomenon also occurs when a Pt film is used in place of the Pd film.

Now, the examples shown in FIGS. 11A and 11B will be described.

First, as shown in FIG. 11A, the gate insulating film 11 of thickness 2.5 nm was formed on the silicon substrate 10. Subsequently, the WSi film 12 of thickness 25 nm was formed by the CVD process. Furthermore, the W film 21 of thickness 25 nm was formed on the WSi film 12 by the PVD process.

Then, as shown in FIG. 11B, the Pd film 22 was formed by the electroless plating process by using PdSO₄ as a plating solution and setting the temperature of the plating tank at 60 to 80° C. and the pH of the plating solution had at 1 to 4. As a result, the W film 21 was replaced with the Pd film 22. A conformal Pd film 22 was formed on the WSi film 12.

The amount of replacement plating depends on plating conditions, for example, a plating time and the concentration of the plating solution. Therefore, all or part of the W film may be replaced with a Pd film by adjusting the plating conditions.

Now, the examples shown in FIGS. 12A and 12B will be described.

First, as shown in FIG. 12A, the gate insulating film 11 of thickness 2.5 nm was formed on the silicon substrate 10. Subsequently, the WSi film 31 was formed by the CVD process. The WSi film 31 was obtained by gradually varying the composition ratio of W to Si in a thickness direction. Specifically, W/Si=about 1/2 near the bottom surface of the WSi film 31, whereas W/Si=about 1/0 near the top surface of the WSi film 31.

Then, as shown in FIG. 12B, the Pd film 22 was formed by the electroless plating process by using PdSO₄ as a plating solution and setting the temperature of the plating tank at 60 to 80° C. and the pH of the plating solution had at 1 to 4. As a result, it was found that the substitution (replacement) reaction between W and Pd was facilitated in an area with a W/Si composition ratio of 1 or more.

When the W/Si composition ratio is gradually varied in the thickness direction, the work function of the WSi film 31 varies in this direction. However, the substantial work function of the gate electrode (the work function determining the electrical characteristics (threshold voltage) of MIS transistors) is determined by the work function of the vicinity of the bottom of the gate electrode (i.e. the vicinity of the interface between the gate electrode and the gate insulating film). Accordingly, even if the W/Si composition ratio is varied in the thickness direction, the substantial work function of the gate electrode can be reduced provided that the percentage of the total amount taken up by Si is large near the bottom of the WSi film (for example, the Si/W composition ratio is 2 or more near the bottom of the WSi film 31).

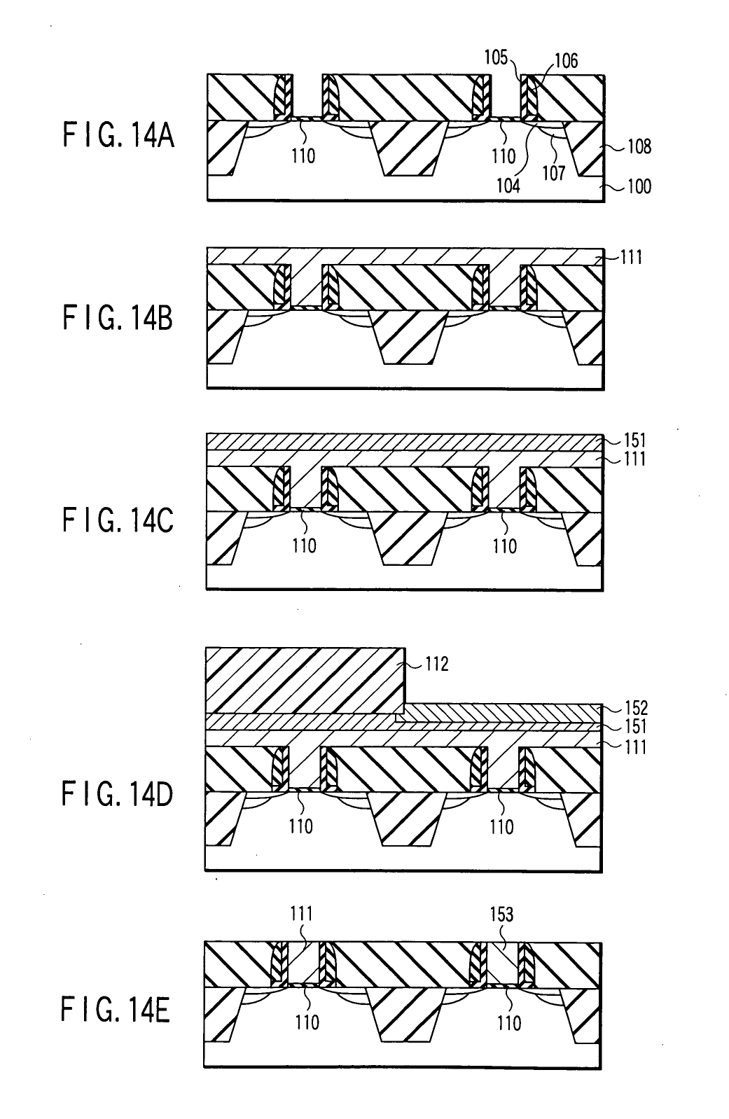

A specific example of the present embodiment will be described with reference to FIGS. 14A to 14E. Those components of this example which correspond to the first embodiment are denoted by the same reference numerals. Their detailed description is thus omitted.

First, the steps from FIGS. 1A to 1E are executed as in the case with the first embodiment.

Then, as shown in FIG. 14A, the plasma oxinitride process is used to form a thin silicon oxinitride film at the bottom of each of the grooves 109 as the gate insulating film 110.

Then, as shown in FIG. 14B, the CVD process is used to deposit the WSiP film 111 all over the surface of the structure as a conducting film. The WSiP film 111 has a work function of 4.3 eV or less. For example, WF₆, SiH₂Cl₂, and PH₅ are used as a source gas. When the W silicide film contains P, the work function can be reduced compared to a W silicide film not containing any P.

Then, as shown in FIG. 14C, a W film 151 of thickness 10 nm is deposited on the WSiP film by the CVD process.

Then, as shown in FIG. 14D, the n type MIS region is covered with the photo resist film 112. Specifically, the photo resist film 112 is formed, as a protecting portion, on a stacked film (first conducting portion) of the WSiP film 111 and W film 151 formed in the n type MIS region. A structure free from the photo resist film 112 is formed on a stacked film (second conducting portion) of the WSiP film 111 and W film 151 formed in the p type MIS region.

Then, the electroplating process is used to form a Pt film (having a work function of about 5.0 eV) 152 (third conducting portion) on that part of the region which is not covered with the photo resist film 112. Specifically, in a plating solution, the upper part of the W film 151 is replaced with the Pt film 152. In this regard, the entire W film 151 may be replaced with the Pt film 152. Pt(NH₃)₂(NO₂)₂ is used as a plating solution. The temperature of a plating tank is 60 to 80° C. The plating solution has a pH of 1 to 4 and a current density of 0.2 to 4 A/cm².

Then, as shown in FIG. 14E, after the photo resist film 112 has been removed, the structure is heated at about 500° C. This allows the Pt in the Pt film 152 to diffuse to the bottom of the WSiP film 111. That is, the Pt diffuses to the vicinity of the interface between the WSiP film 111 and the gate insulating film 110. As a result, a film (PtWSiP film 153) containing Pt, W, Si, and P is formed in the p type MIS region. Further, the Pt film 152 and the WSiP film 111 react thermally with each other to suck the Si from the WSiP film 111. This reduces the amount of Si contained in the PtWSiP film 153. The W film and the Pt film 152 both have high work functions: the W film has a work function of about 4.9 eV, and the Pt film has a work function of about 5.0 eV. Therefore, at least the bottom of the PtWSiP film 153 (at least the vicinity of the interface between the PtWSiP film 153 and the gate insulating film 110) has a work function of about 4.8 eV or more.

Then, the CMP process is used to remove those parts of the WSiP film 111, W film 151, and PtWSiP film 153 which are located outside the grooves. Thus, a gate electrode of the WSiP film 111 is formed in the n type MIS region. A gate electrode of the PtWSiP film 153 is formed in the p type MIS region.

Thus, a CMOS transistor is obtained in which the gate electrode of the n type MIS transistor is composed of the WSiP film 111, having a low work function, and in which the gate electrode of the p type MIS transistor is composed of the PtWSiP film 153, having a higher work function than the WSiP film.

As described above, according to the present embodiment, in the present embodiment, a semiconductor device of a dual metal gate structure which has excellent characteristics and reliability is obtained by diffusing the metal elements from the upper conducting portion (third conducting portion), formed by the plating process, to the lower conducting portion (second conducting portion), as in the case with the first embodiment. Further, in the present embodiment, the W film is formed on the WSiP film to prevent formation of an oxide film on the WSiP film in the plating solution. Consequently, the W film can be easily replaced with a Pt film. Therefore, a good and flat Pt film can be formed to provide a semiconductor device having excellent characteristics and reliability.

(Embodiment 8)

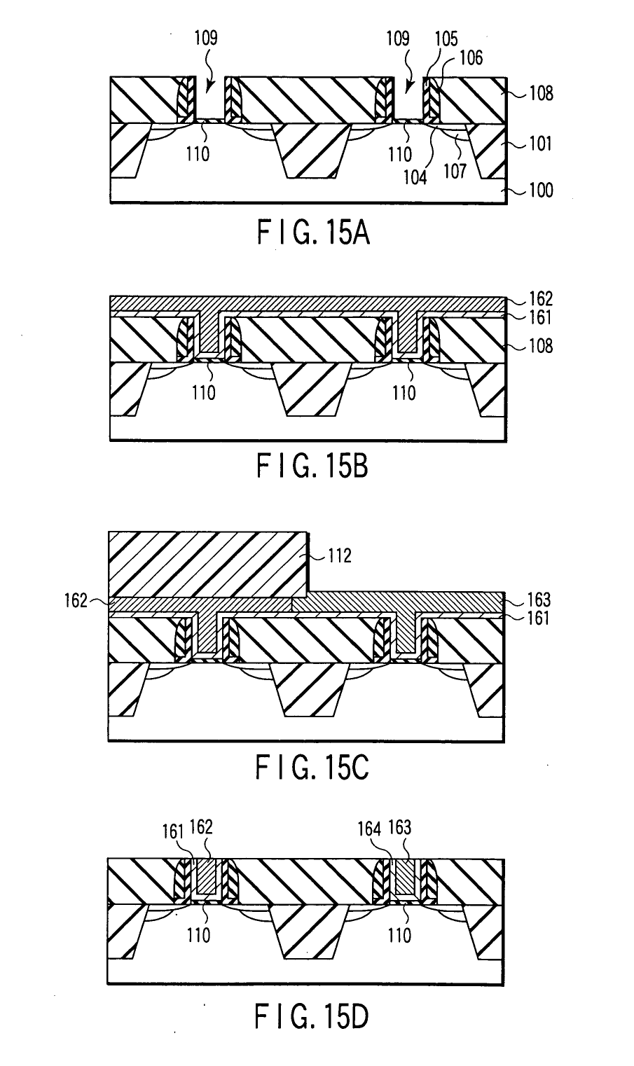

FIGS. 15A to 15D are sectional views schematically showing a manufacturing method for a semiconductor device according to an eighth embodiment of the present invention. Those components of this embodiment which correspond to the first embodiment are denoted by the same reference numerals. Their detailed description is thus omitted.

First, the steps from FIGS. 1A to 1E are executed as in the case with the first embodiment.

Then, as shown in FIG. 15A, the plasma oxinitride process is used to form a thin silicon oxinitride film at the bottom of each of the grooves 109 as the gate insulating film 110.

Then, as shown in FIG. 15B, a TaN film (having a work function of 4.3 eV or less) 161 is formed on the gate insulating film 110 and interlayer insulating film 108 by the CVD process. However, the TaN film 161 is formed to be thin along each groove 109 so as not to fill up the grooves 109 completely. Furthermore, an Mo film 162 is formed on the TaN film 161 by the CVD process.

Then, as shown in FIG. 15C, the n type MIS region is covered with the photo resist film 112. Specifically, the photo resist film 112 is formed, as a protecting portion, on a stacked film (first conducting portion) of the TaN film 161 and Mo film 162 formed in the n type MIS region. A structure free from the photo resist film 112 is formed on a stacked film (second conducting portion) of the TaN film 161 and Mo film 162 formed in the p type MIS region.

Then, the electroless plating process is used to form a Pd film (having a work function of about 5.0 eV) 163 (third conducting portion) on that part of the region which is not covered with the photo resist film 112. Specifically, in a plating solution, the Mo film 162 is replaced with the Pd film 163. PdSO₄ is used as a plating solution. The temperature of a plating tank is 60 to 80° C. The plating solution has a pH of 1 to 4.

Then, as shown in FIG. 15D, after the photo resist film 112 has been removed, the structure is heated at about 500° C. This allows the Pd in the Pd film 163 to diffuse to the bottom of the TaN film 161. That is, the Pd diffuses to the vicinity of the interface between the TaN film 161 and the gate insulating film 110. As a result, a TaN film 164 containing Pd is formed in the p type MIS region. Therefore, at least the bottom of the TaN film 164 containing Pd (at least the vicinity of the interface between the TaN film 164 containing Pd and the gate insulating film 110) has a work function of about 4.8 eV or more. Subsequently, the CMP process is used to flatten the surface of the structure. A gate electrode formed of the TaN film 161 and the Mo film 162 is formed in the n type MIS region. A gate electrode formed of TaN film 164 containing Pd and the Pd film 163 is formed in the p type MIS region. In this case, the gate electrode of the n type MIS transistor has a stacked structure composed of the TaN film 161 and the Mo film 162. However, Mo cannot be diffused through the TaN film 161 when heated at about 500° C. Therefore, the work function of the vicinity of the bottom of the gate electrode of the n type MIS transistor does not increase.

Thus, a CMOS transistor is obtained in which the n type MIS transistor has a gate electrode having a low work function, and in which the p type MIS transistor has a gate electrode having a high work function.

In forming the Pd film by electroless plating, a Pd film containing B may be formed using as a reducing agent a boron compound such as dimethylammineboron (DMAB:(CH₃)₂NHBH₃). In this case, the B, having a work function of 4.8 eV or more, can be diffused to the vicinity of the gate insulating film simultaneously with the Pd. It is thus possible to increase the work function of the gate electrode of the p type MIS transistor.

As described above, also in the present embodiment, it is possible to obtain a semiconductor device of a dual metal gate structure which has excellent characteristics and reliability, as in the case with the seventh embodiment. Further, according to the present embodiment, the resistance of the gate electrode can be reduced because the highly conductive metal film is stacked in the upper layer portion in the gate electrodes of the n type MIS transistor and the p type MIS transistor.

(Embodiment 9)

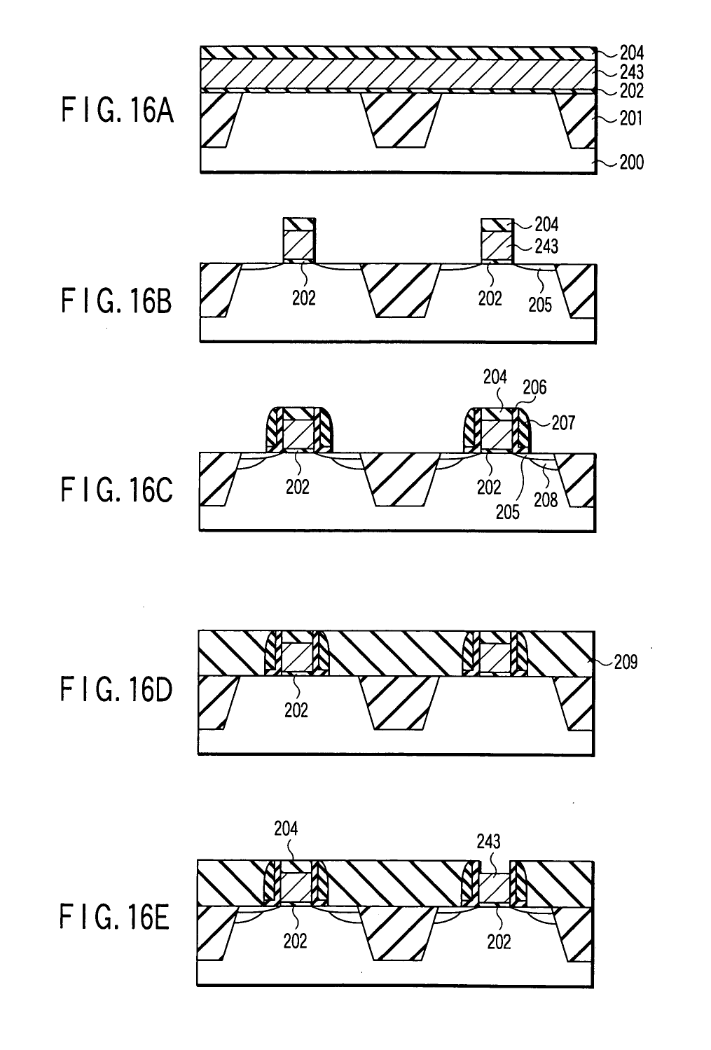

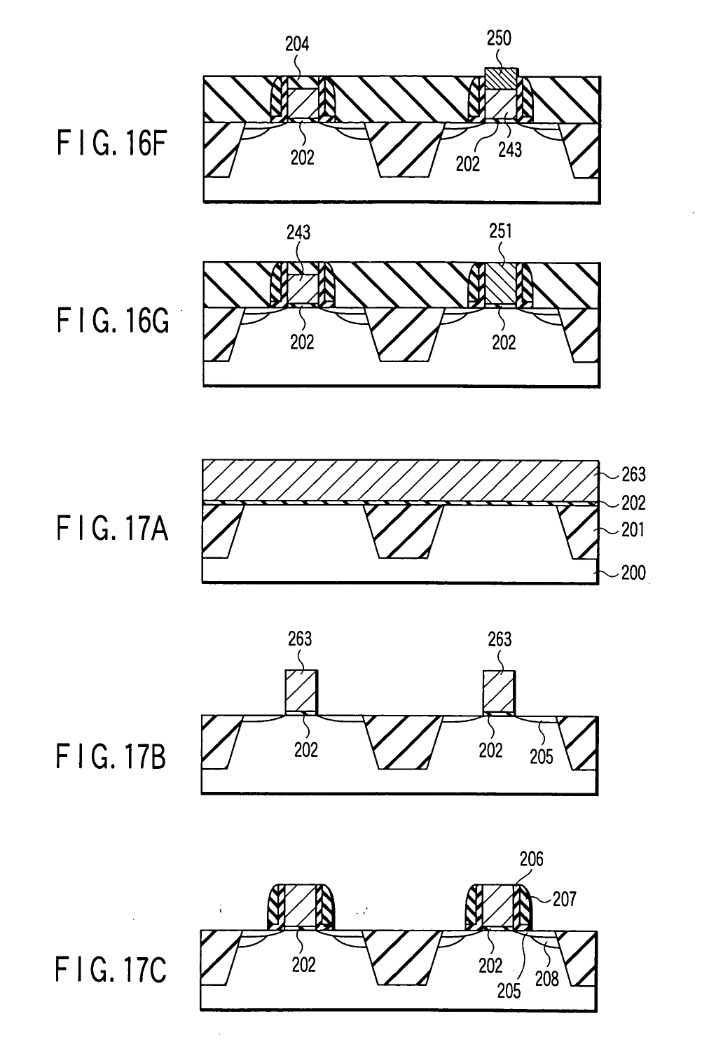

FIGS. 16A to 16G are sectional views schematically showing a manufacturing method for a semiconductor device according to a ninth embodiment of the present invention.

First, as shown in FIG. 16A, the gate insulating film 202 is formed on the single-crystal silicon substrate (semiconductor substrate) 200 having the isolation region 201. Subsequently, a WSi film 243 is deposited on the gate insulting film 202 by the CVD process. WF₆ and SiH₂Cl₂ are used as a source gas. The WSi film 243 is obtained by gradually varying the composition ratio of W to Si in the thickness direction. Specifically, W/Si=about 1/2 near the bottom surface of the WSi film 243, whereas W/Si=about 1/0 near the top surface of the WSi film 243. Furthermore, the silicon nitride film 204 is formed on the WSi film 243 by the CVD process.

Then, as shown in FIG. 16B, the silicon nitride film 204 and the WSi film 243 are patterned by anisotropic etching to form electrode structures. Subsequently, As⁺ ions are implanted into the n type MIS region. B⁺ ions are implanted into the p type MIS region. Furthermore, thermal treatment at 800° C. is carried out for five seconds to form the diffusion layer 205 as a part of a source and drain area.

Then, as shown in FIG. 16C, the silicon oxide film 206 and the silicon nitride film 207 are deposited. Subsequently, an etchback operation is performed to leave the silicon nitride film 206 and the silicon oxide film 207 on side walls of the electrode structures. Subsequently, P⁺ ions are implanted into the n type MIS region. B⁺ ions are implanted into the p type MIS region. Furthermore, thermal treatment at 900° C. is carried out for five seconds to form the diffusion layer 208 as a part of the source and drain area.

Then, as shown in FIG. 16D, the interlayer insulating film 209 is deposited all over the surface of the resultant structure. Subsequently, the interlayer insulating film 209 is flattened by chemical mechanical polishing (CMP) to expose the surface of the silicon nitride film 204.

Then, as shown in FIG. 16E, the silicon nitride film 204 is removed from the p type MIS region. Thus, the silicon nitride film 204 is formed, as a protecting portion, on the WSi film (first conducting portion) 243 formed in the n type MIS region. A structure free from the silicon nitride film 204 is formed on the WSi film 243 (second conducting portion) formed in the p type MIS region.

Then, as shown in FIG. 16F, the electroless plating process is used to form an Ni film (having a work function of about 4.8 eV or more) 250 (third conducting portion) on that part of the region which is not covered with the silicon nitride film 204. NiSO₄ is used as a plating solution. The temperature of the plating tank is 60 to 80° C. The plating solution has a pH of 5 to 10. Thus, the use of the plating process enables the Ni film 250 to be formed only in a conductive region, i.e. only in the exposed region of the WSi film 243. Further, the substitution (replacement) reaction between W and Ni is facilitated in an area with a W/Si composition ratio of 1 or more. That is, in the plating solution, the upper part of the WSi film 243 is replaced with the Ni film 250.

Then, as shown in FIG. 16G, the resultant structure is heated at about 500° C. This allows the Ni in the Ni film 250 to diffuse to the bottom of the WSi film 243. That is, the Ni diffuses to the vicinity of the interface between the WSi film 243 and the gate insulating film 202. As a result, a WSi film 251 containing Ni is formed in the p type MIS region. Therefore, at least the bottom of the WSi film 251 containing Ni (at least the vicinity of the interface between the WSi film 251 containing Ni and the gate insulating film 202) has a work function of about 4.8 eV or more. Subsequently, the CMP process is used to flatten the surface of the structure. Thus, a gate electrode formed of the WSi film 243 is formed in the n type MIS region. A gate electrode formed of the WSi film 251 containing Ni is formed in the p type MIS region.

Thus, a CMOS transistor is obtained in which the n type MIS transistor has a gate electrode having a low work function, and in which the p type MIS transistor has a gate electrode having a high work function.

As described above, also in the present embodiment, it is possible to obtain a semiconductor device of a dual metal gate structure which has excellent characteristics and reliability, as in the seventh embodiment.

(Embodiment 10)

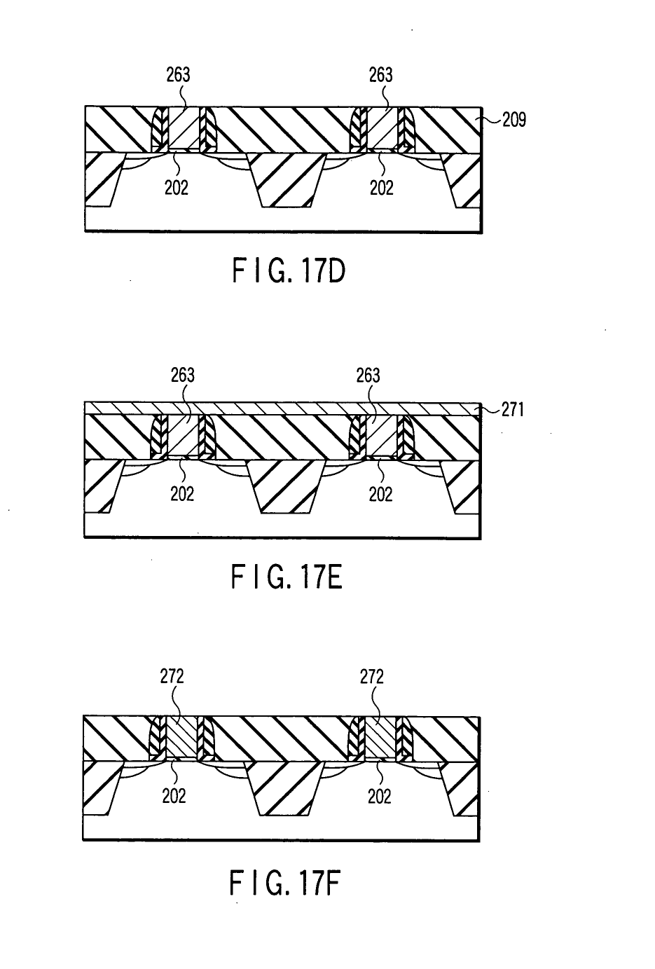

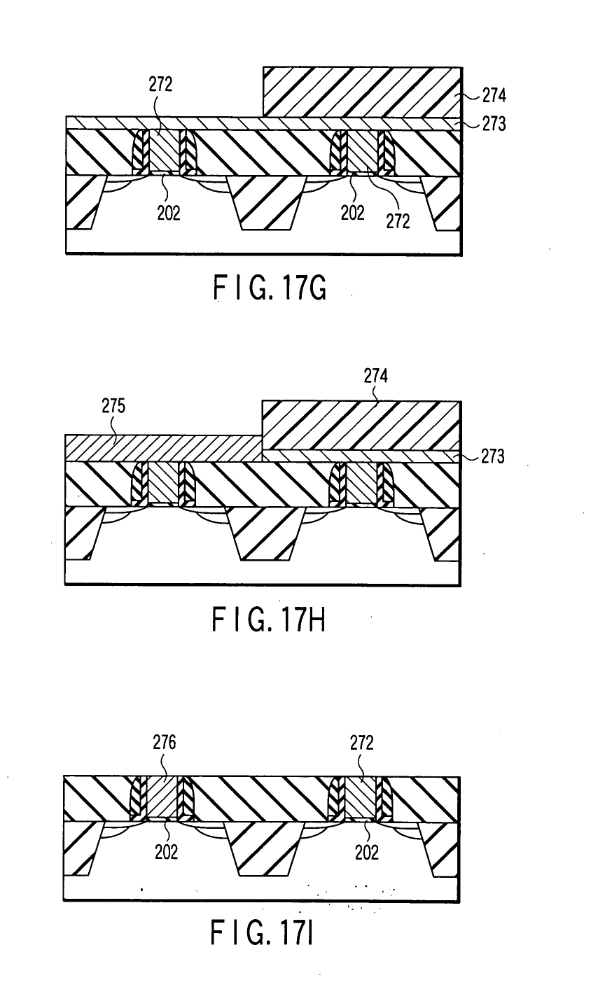

FIGS. 17A to 17I are sectional views schematically showing a manufacturing method for a semiconductor device according to a tenth embodiment of the present invention.

First, as shown in FIG. 17A, the gate insulating film (silicon oxide film) 202 is formed on the single-crystal silicon substrate (semiconductor substrate) 200 having the isolation region 201. Subsequently, a polycrystalline silicon film 263 is deposited on the silicon oxide film 202.

Then, as shown in FIG. 17B, the polycrystalline silicon film 263 is subjected to anisotropic etching to form gate structures. Subsequently, As⁺ ions are implanted into the n type MIS region. B⁺ ions are implanted into the p type MIS region. Furthermore, thermal treatment at 800° C. is carried out for five seconds to form the diffusion layer 205 as a part of a source and drain area.

Then, as shown in FIG. 17C, the silicon nitride film 206 and the silicon oxide film 207 are deposited all over the surface of the resultant structure. Subsequently, an etchback operation is performed to leave the silicon nitride film 206 and the silicon oxide film 207 on side walls of the gate structures. Subsequently, P⁺ ions are implanted into the n type MIS region. B⁺ ions are implanted into the p type MIS region. Furthermore, thermal treatment at 800° C. is carried out for five seconds to form the diffusion layer 208 as a part of the source and drain area.

Then, as shown in FIG. 17D, the interlayer insulating film 209 is deposited all over the surface of the resultant structure. Subsequently, the interlayer insulating film 209 is flattened by chemical mechanical polishing (CMP) to expose the surface of the polycrystalline silicon film 263.

Then, as shown in FIG. 17E, an Ni film 271 is formed all over the surface of the structure by the PVD process.

Then, as shown in FIG. 17F, thermal treatment at 400° C. is carried out for 30 seconds to allow the Ni film 271 to react with the polycrystalline silicon film 263 to form an Ni silicide film (having a work function of 4.8 eV or more) 272. The unchanged part of the Ni film 271 is removed using, for example, a mixture of sulfuric acid and hydrogen peroxide.

Then, as shown in FIG. 17G, a W film 273 of thickness 10 nm is formed all over the surface of the resultant structure by the PVD process. Furthermore, the p type MIS region is covered with a photo resist film 274. Specifically, the photo resist film 274 is formed, as a protecting portion, on a stacked film (first conducting portion) of the Ni silicide film 272 and W film 273 formed in the p type MIS region. A structure free from the photo resist film 274 is formed on a stacked film (second conducting portion) of the Ni silicide film 272 and W film 273 formed in the n type MIS region.

Then, as shown in FIG. 17H, the electroless plating process is used to form an In film (having a work function of about 4.1 eV) 275 (third conducting portion) on that part of the structure which is not covered with the photo resist film 274. That is, in a plating solution, the W film 273 is replaced with the In film 275. In₂(SO₄)₃ is used as the plating solution. The temperature of the plating tank is 60 to 80° C. The plating solution has a pH of 8 to 9.

Then, as shown in FIG. 17I, after the photo resist film 274 has been removed, the resultant structure is heated at about 500° C. This allows the In in the In film 275 to diffuse to the bottom of the Ni silicide film 272. That is, the In diffuses to the vicinity of the interface between the Ni silicide film 272 and the gate insulating film 202. As a result, an Ni silicide film 276 containing In is formed in the n type MIS region. Therefore, at least the bottom of the Ni silicide film 276 containing In (at least the vicinity of the interface between the Ni silicide film 276 containing In and the gate insulating film 202) has a work function of about 4.3 eV or less. Subsequently, the CMP process is used to flatten the surface of the structure. Thus, a gate electrode formed of the Ni silicide film 276 containing In is formed in the n type MIS region. A gate electrode formed of the Ni silicide film 272 is formed in the p type MIS region.

Thus, a CMOS transistor is obtained in which the n type MIS transistor has a gate electrode having a low work function, and in which the p type MIS transistor has a gate electrode having a high work function.

As described above, also in the present embodiment, it is possible to obtain a semiconductor device of a dual metal gate structure which has excellent characteristics and reliability, as in the seventh embodiment.

In forming the In film by electroless plating, an In film containing P may be formed using a phosphorous compound as a reducing agent. In this case, the P, having a work function of 3.8 eV or less, can be diffused to the vicinity of the gate insulating film simultaneously with the In. It is thus possible to reduce the work function of the gate electrode of the n type MIS transistor.

(Embodiment 11)

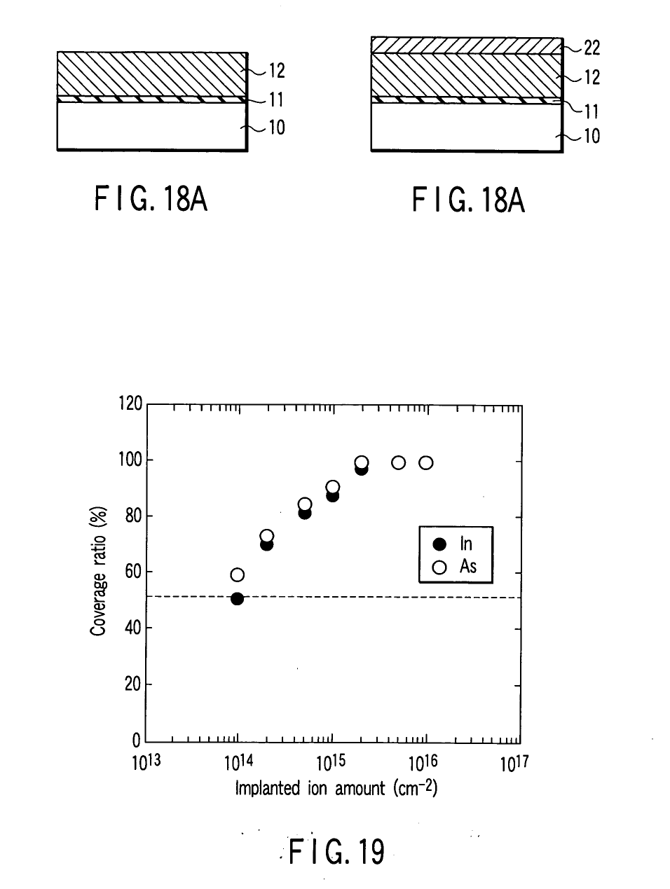

First, the principle of the present embodiment will be described. As described in the seventh embodiment, when a Pd film is formed on a WSi film by plating, the Pd film may be prevented from being appropriately formed. Thus, an attempt was made to apply the method described below. This method will be described with reference to FIGS. 18A and 18B.

First, as shown in FIG. 18A, the gate insulating film 11 of thickness 2.5 nm was formed on the silicon substrate 10. Subsequently, the WSi film 12 of thickness 50 nm was formed by the CVD method. Subsequently, In ions are implanted in a surface region of the WSi film 12.

Then, as shown in FIG. 18B, the Pd film 22 was formed by electroless plating by using PdSO₄ as a plating solution and setting the temperature of a plating tank at 60 to 80° C. and the pH of the plating solution at 1 to 4. As a result, although a very thin silicon oxide film was formed at the boundary between the WSi film 12 and the Pd film 22, it was possible to form the Pd film 22 to be conformal. As already described, electrons must be moved between a plating material and a material to be plated in order to achieve plating. In the present example, the Pd film 22 is expected to have been formed to be conformal because the In introduced into the Wsi film 12 by ion implantation facilitated the movement of electrons, resulting in a quick substitution (replacement) reaction between Pd and W.

FIG. 19 shows the relationship between the amount of In and As ions implanted and the coverage ratio of the Pd film on the surface of the WSi film. If no ions are implanted, the coverage ratio is about 50%. When the amount of ions implanted is about 1×10¹⁴ cm⁻² or more, the coverage ratio of the Pd film is improved. When the amount of ions implanted is about 1×10¹⁵ cm⁻² or more, the coverage ratio is almost 100%, thus making it possible to form a uniform Pd film.

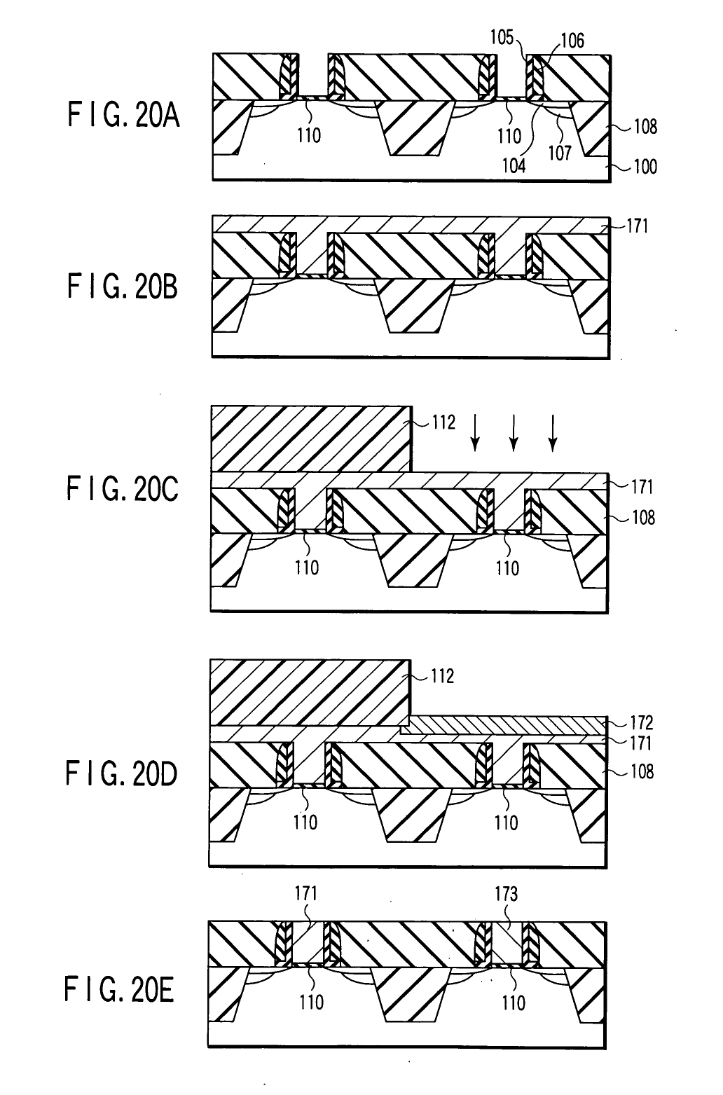

A specific example of the present embodiment will be described with reference to FIGS. 20A to 20E. Those components of this example which correspond to the first embodiment are denoted by the same reference numerals. Their detailed description is thus omitted.

First, the steps from FIGS. 1A to 1E are executed as in the case with the first embodiment. Then, as shown in FIG. 20A, the plasma oxinitride process is used to form a thin silicon oxinitride film at the bottom of each of the grooves as the gate insulating film 110.

Then, as shown in FIG. 20B, the CVD process is used to deposit a WSi film 171 all over the surface of the structure as a conducting film. The WSi film 171 has a work function of 4.3 eV or less. For example, WF₆ and SiH₂Cl₂ are used as a source gas.

Then, as shown in FIG. 20C, the n type MIS region is covered with the photo resist film 112. Specifically, the photo resist film 112 is formed, as a protecting portion, on the WSi film 171 (first conducting portion) formed in the n type MIS region. A structure free from the photo resist film 112 is formed on the WSi film 171 (second conducting portion) formed in the p type MIS region. Then, the photo resist film 112 is used as a mask to implant In ions in the surface region of the WSi film 171 formed in the p type MIS region. As conditions for ion implantation, the acceleration voltage and the amount of ions implanted are set at 50 keV and 1×10¹⁶ cm⁻², respectively.

Then, as shown in FIG. 20D, the electroplating process is used to form a Pt film (having a work function of about 5.0 eV) 172 (third conducting portion) on the region that is not covered with the photo resist film 112. Specifically, the implanted In ions cause a substitution (replacement) reaction between W and Pt in a plating solution to replace the upper part of the W film 171 with the Pt film 172. Pt(NH₃)₂(NO₂)₂ is used as a plating solution. The temperature of the plating tank is set at 60 to 80° C. The plating solution has a pH of 1 to 4 and a current density of 0.2 to 4 A/cm².

Then, as shown in FIG. 20E, after the photo resist film 112 has been removed, the structure is heated at a temperature of about 500° C. This allows the Pt in the Pt film 172 to diffuse to the bottom of the WSi film 171. That is, the Pt diffuses to the vicinity of the interface between the WSi film 171 and the gate insulating film 110. As a result, a film (PtWSiIn film 173) containing Pt, W, Si, and In is formed in the p type MIS region. Further, the Pt film 172 and the WSi film 171 react thermally with each other to suck the Si from the WSi film 171. This serves to reduce the amount of Si contained in the PtWSiIn film 173. The W film and the Pt film 152 both have high work functions: the W film has a work function of about 4.9 eV, and the Pt film has a work function of about 5.0 eV. Therefore, at least the bottom of the PtWSiIn film 173 (at least the vicinity of the interface between the PtWSiIn film 173 and the gate insulating film 110) has a work function of about 4.8 eV or more.

Then, the CMP process is used to remove those parts of the WSi film 171 and PtWSiIn film 173 which are located outside the grooves. Thus, a gate electrode formed of the WSi film 171 is formed in the n type MIS region. A gate electrode formed of the PtWSiIn film 173 is formed in the p type MIS region.

Thus, a CMOS transistor is obtained in which the gate electrode of the n type MIS transistor is composed of the WSi film 171, having a low work function, and in which the gate electrode of the p type MIS transistor is composed of the PtWSiIn film 173, having a higher work function than the WSi film.

As described above, in the present embodiment, a semiconductor device of a dual metal gate structure which has excellent characteristics and reliability is obtained by diffusing the metal elements from the upper conducting portion (third conducting portion), formed by the plating process, to the lower conducting portion (second conducting portion), as in the case with the first embodiment. Further, in the present embodiment, by implanting In ions in the surface region of the WSi film, the upper part of the WSi film can be easily replaced with the Pt film during the plating process. Therefore, a good and flat Pt film can be formed to provide a semiconductor device having excellent characteristics and reliability.

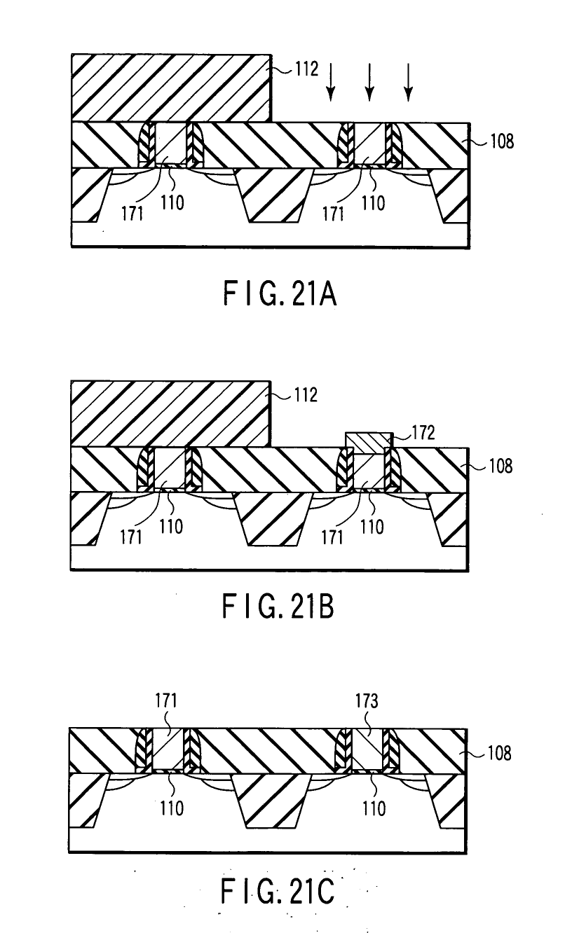

FIGS. 21A to 21C are sectional views schematically showing a manufacturing method for a semiconductor device according to a variation of the present embodiment. Those components of this variation which correspond to the above described embodiment are denoted by the same reference numerals. Their detailed description is thus omitted.

First, the steps shown in FIGS. 20A and 20B are executed as in the case with the above described embodiment. Then, as shown in FIG. 21A, the CMP process is used to remove those parts of the WSi film 171 which are located outside the grooves. Subsequently, the n type MIS region is covered with the photo resist film 112. Moreover, the photo resist film 112 is used as a mask to implant In ions in the surface region of the WSi film 171 formed in the p type MIS region.

Then, as shown in FIG. 21B, the electroplating process is executed to form the Pt film 172 in a region that is not covered with the photo resist film 112. Specifically, the implanted In ions cause a substitution (replacement) reaction between W and Pt to replace the upper part of the Wsi film 171 with the Pt film 172. In the present variation, the Pt film 172 is formed only in the conductive region, i.e. the region in which the WSi film 171 is exposed.

Then, as shown in FIG. 21C, the photo resist film 112 is removed. Subsequently, the structure is heated at a temperature of 500° C. Thus, as in the case with the above described embodiment, the gate electrode formed of the WSi film 171 is formed in the n type MIS region, while the gate electrode formed of the PtWSiIn film 173 is formed in the p type MIS region.

(Embodiment 12)

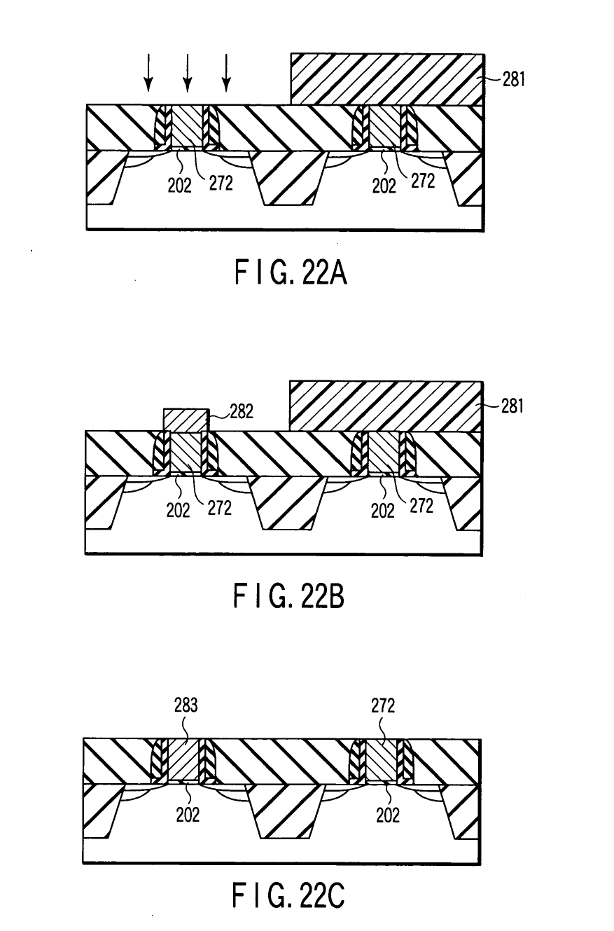

FIGS. 22A to 22C are sectional views schematically showing a manufacturing method for a semiconductor device according to a twelfth embodiment of the present embodiment. Since several consecutive steps of this method are similar to the corresponding ones of the tenth embodiment, shown in FIGS. 17A to 17I. Accordingly, those components of this embodiment which correspond to the tenth embodiment are denoted by the same reference numerals, and their detailed description is thus omitted.

After the step shown in FIG. 17F, as shown in FIG. 22A, the p type MIS region is covered with a photo resist film 281. Specifically, the photo resist film 281 is formed, as a protecting portion, on the Ni silicide film 272 (first conducting portion) formed in the p type MIS region. A structure free from the photo resist film 281 is formed on the Ni silicide film 272 (second conducting portion) formed in the n type MIS region. Then, the photo resist film 281 is used as a mask to implant In ions in the surface region of the Ni silicide film 272 formed in the n type MIS region. As conditions for ion implantation, the acceleration voltage and the amount of ions implanted are set at 25 keV and 1×10¹⁶ cm⁻², respectively.

Then, as shown in FIG. 22B, the electroless plating process is used to form an In film (having a work function of about 4.1 eV) 282 (third conducting portion) on the region that is not covered with the photo resist film 281. Specifically, the implanted In ions cause a substitution (replacement) reaction between Ni and In in a plating solution to form the In film 282 on the Ni silicide film 272. In₂(SO₄)₃ is used as a plating solution. The temperature of the plating tank is set at 60 to 80° C. The plating solution has a pH of 8 to 9.

Then, as shown in FIG. 22C, after the photo resist film 281 has been removed, the structure is heated at a temperature of about 500° C. This allows the In in the In film 282 to diffuse to the bottom of the Ni silicide film 272. That is, the In diffuses to the vicinity of the interface between the Ni silicide film 272 and the gate insulating film 202. As a result, an Ni silicide film 283 containing In is formed in the n type MIS region. Therefore, at least the bottom of the Ni silicide film 283 containing In (at least the vicinity of the interface between the Ni silicide film 283, containing In, and the gate insulating film 202) has a work function of about 4.3 eV or less. Subsequently, the CMP process is used to carry out flattening. Thus, a gate electrode formed of the Ni silicide film 283 containing In is formed in the n type MIS region. A gate electrode formed of the Ni silicide film 272 is formed in the p type MIS region.

In this manner, a CMOS transistor is obtained in which the n type MIS transistor has a gate electrode having a low work function and in which the p type MIS transistor has a gate electrode having a high work function.

As described above, in the present embodiment, a semiconductor device of a dual metal gate structure is obtained which has excellent characteristics and reliability, as in the case with the eleventh embodiment.

In forming an In film by electroless plating, a phosphorous compound may be used as a reducing agent to form an In film containing P. In this case, it is possible to diffuse P, having a work function of 3.8 eV or less, to the vicinity of the gate insulating film simultaneously with In. It is thus possible to reduce the work function of the gate electrode of the n type MIS transistor.

In the above described eleventh and twelfth embodiments, In is used as an element implanted as ions. However, it is possible to use an impurity element such as P, As, B, Al, Ga, or Sb which is electrically activated in silicon. Furthermore, a method using ion implantation such as those described in the eleventh and twelfth embodiments can be applied to other embodiments as required. In particular, if a conducting portion containing silicon is plated, an appropriate plated film can be formed by introducing a predetermined element by ion implantation.

The first to twelfth embodiments have been described above. However, these embodiments can be changed as described above.

To allow the diffusion of the metal elements from the plated film of the gate electrode of the p type MIS transistor, the first, second, and third conducting portions can generally be configured as described below.

The first and second conducting portions can each be composed of a conducting film containing a compound containing W and Si, a conducting film containing a compound containing Mo and Si, a conducting film containing a compound containing Ta and Si, or a conducting film containing a compound containing Nb and Si. Specifically, the compound may be WSi, WSiN, MoSi, MoSiN, TaSi, TaSiN, NbSi, NbSiN, or the like. Alternatively, the first and second conducting portions can each be composed of a conducting film containing a conductor containing Ta, a conductor containing Nb, or a conductor containing Cr.

The third conducting portion can be composed of a metal film containing at least one of Pt, Pd, Ni, Co, Rh, Ir, Sb, and Bi. The plating solution can be composed of a metal salt of these metal elements. Specifically, the plating solution can be composed of Pt(NH₃)₂(NO₂)₂, PtCl₆(NH₄)₂, H₂PtCl₆, (NH₃)₂Pd(NO₂), PdCl₄, PdSO₄, NiCl₂, NiSO₄, Ni(NH₂SO₃)₂, CoSO₄, Rh₂(SO₄)₂, Rh(PO₄), IrCl₄, or the like.

To allow the diffusion of the metal elements from the plated film of the gate electrode of the p type MIS transistor, it is preferable that the bottom of the second conducting portion have a higher work function after the diffusion of the metal elements than before the diffusion of the metal elements. In this case, the bottom of the second conducting portion preferably has a work function of 4.8 eV or more after the diffusion of the metal elements. The bottom of the second conducting portion preferably has a work function of 4.3 eV or less before the diffusion of the metal elements. Furthermore, the third conducting portion preferably has a higher work function than the bottom of the second conducting portion before the diffusion of the metal elements. In this case, preferably, the third conducting portion has a work function of 4.8 eV or more and the bottom of the second conducting portion preferably has a work function of 4.3 eV or less before the diffusion of the metal elements.

To allow the diffusion of the metal elements from the plated film of the gate electrode of the n type MIS transistor, the first, second, and third conducting portions can be composed of the conducting materials described below.

The first and second conducting portions can each be composed of a conducting film containing a W film or an Mo film. Alternatively, the first and second conducting portions can each be composed of a conducting film containing a conductor containing at least one of Pt, Pd, Ni, Rh, and Ir. Furthermore, the first and second conducting portions can each be composed of a conducting film containing a compound containing Pt and Si, a conducting film containing a compound containing Pd and Si, a conducting film containing a compound containing Ni and Si, a conducting film containing a compound containing Rh and Si, and a conducting film containing a compound containing Ir and Si. Specifically, the compound may be NiSi, NiSiN, PtSi, PdSi, or other silicon compounds.

The third conducting portion can be composed of a metal film containing at least one of In and Tl. The plating solution can be composed of a metal salt of these metal elements. Specifically, the plating solution can be composed of In₂(SO₄)₃, In₂S₃, InCl₂, TlCl₂, TlBr₂, or the like.

To allow the diffusion of the metal elements from the plated film of the gate electrode of the n type MIS transistor, it is preferable that the bottom of the second conducting portion have a lower work function after the diffusion of the metal elements than before the diffusion of the metal elements. In this case, the bottom of the second conducting portion preferably has a work function of 4.3 eV or less after the diffusion of the metal elements. The bottom of the second conducting portion preferably has a work function of 4.8 eV or more before the diffusion of the metal elements. Furthermore, the third conducting portion preferably has a lower work function than the bottom of the second conducting portion before the diffusion of the metal elements. In this case, preferably, the third conducting portion has a work function of 4.3 eV or less and the bottom of the second conducting portion preferably has a work function of 4.8 eV or more before the diffusion of the metal elements.

Further, in the above embodiments, the plating process can be composed of electroplating or electroless plating.

Furthermore, in the above embodiments, the gate insulating film may be a silicon oxide film, a silicon nitride film, or a silicon oxinitride film. Alternatively, the gate insulating film may have a higher dielectric constant than the silicon oxide film. Such an insulating film can be composed of, for example, an Hf oxide, a Zr oxide, a Ti oxide, a Ta oxide, an Al oxide, an Sr oxide, a Y oxide, or an La oxide. Alternatively, these oxides may contain silicon as in the case with, for example, ZrSiₓO_{y}.

Moreover, the methods shown in the above embodiments can be properly combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A manufacturing method for a semiconductor device comprising a first conduction type MIS transistor provided in a first region and a second conduction type MIS transistor provided in a second region, the method comprising:
forming a structure comprising a first gate insulating film provided in the first region, a first conducting portion provided on the first gate insulating film, a second gate insulating film provided in the second region, and a second conducting portion provided on the second gate insulating film, the first conducting portion and second conducting portion being formed of the same conducting film, a work function of a bottom of the first conducting portion being equal to a work function of a bottom of the second conducting portion;
forming a third conducting portion on the second conducting portion by a plating method; and
varying the work function of the bottom of the second conducting portion by diffusing a metal element contained in the third conducting portion to the second conducting portion.

2. The manufacturing method for a semiconductor device according to claim 1, wherein the first conduction type MIS transistor is an n type MIS transistor, and the second conduction type MIS transistor is a p type MIS transistor, and wherein a work function of the bottom of the second conducting portion obtained after the metal element is diffused is higher than that obtained before the metal element is diffused.

3. The manufacturing method for a semiconductor device according to claim 1, wherein the first conduction type MIS transistor is an n type MIS transistor, and the second conduction type MIS transistor is a p type MIS transistor, and wherein a work function of the third conducting portion is higher than a work function of the bottom of the second conducting portion obtained before the metal element is diffused.

4. The manufacturing method for a semiconductor device according to claim 1, wherein the first conduction type MIS transistor is a p type MIS transistor, and the second conduction type MIS transistor is an n type MIS transistor, and wherein a work function of the bottom of the second conducting portion obtained after the metal element is diffused is lower than that obtained before the metal element is diffused.

5. The manufacturing method for a semiconductor device according to claim 1, wherein the first conduction type MIS transistor is a p type MIS transistor, and the second conduction type MIS transistor is an n type MIS transistor, and wherein a work function of the third conducting portion is lower than a work function of the bottom of the second conducting portion obtained before the metal element is diffused.

6. The manufacturing method for a semiconductor device according to claim 1, wherein the structure further comprises a protecting portion provided on the first conducting portion.

7. The manufacturing method for a semiconductor device according to claim 1, wherein forming the structure comprises:
forming an insulating portion having a first groove in the first region and a second groove in the second region;
forming the first gate insulating film and the second gate insulating film in the first groove and the second groove, respectively;
forming the first conducting portion and the second conducting portion on the first gate insulating film and the second gate insulating film, respectively; and
forming a protecting portion on the first conducting portion.

8. The manufacturing method for a semiconductor device according to claim 7, wherein the first conducting portion includes a portion formed on the insulating portion, and the second conducting portion includes a portion formed on the insulating portion.

9. The manufacturing method for a semiconductor device according to claim 1, wherein forming the structure comprises:
forming a first structure portion including the first conducting portion and a protecting portion on the first conducting portion and a second structure portion including the second conducting portion and a dummy protecting portion on the second conducting portion;
forming an insulating portion surrounding the first structure portion and the second structure portion; and
removing the dummy protecting portion.

10. The manufacturing method for a semiconductor device according to claim 1, further comprising implanting a predetermined element into the second conducting portion before forming the third conducting portion on the second conducting portion.

11. A manufacturing method for a semiconductor device comprising a first conduction type MIS transistor provided in a first region and a second conduction type MIS transistor provided in a second region, the method comprising:
forming a structure comprising a first gate insulating film provided in the first region, a first conducting portion provided on the first gate insulating film, a second gate insulating film provided in the second region, and a second conducting portion provided on the second gate insulating film, the first conducting portion and second conducting portion being formed of the same conducting film, a work function of a bottom of the first conducting portion being equal to a work function of a bottom of the second conducting portion;
replacing an upper part of the second conducting portion with a third conducting portion by a plating method; and
varying the work function of the bottom of the second conducting portion by diffusing a metal element contained in the third conducting portion to a lower part of the second conducting portion.

12. The manufacturing method for a semiconductor device according to claim 11, wherein the first conduction type MIS transistor is an n type MIS transistor, and the second conduction type MIS transistor is a p type MIS transistor, and wherein a work function of the bottom of the second conducting portion obtained after the metal element is diffused is higher than that obtained before the metal element is diffused.

13. The manufacturing method for a semiconductor device according to claim 11, wherein the first conduction type MIS transistor is an n type MIS transistor, and the second conduction type MIS transistor is a p type MIS transistor, and wherein a work function of the third conducting portion is higher than a work function of the bottom of the second conducting portion obtained before the metal element is diffused.

14. The manufacturing method for a semiconductor device according to claim 11, wherein the first conduction type MIS transistor is a p type MIS transistor, and the second conduction type MIS transistor is an n type MIS transistor, and wherein a work function of the bottom of the second conducting portion obtained after the metal element is diffused is lower than that obtained before the metal element is diffused.

15. The manufacturing method for a semiconductor device according to claim 11, wherein the first conduction type MIS transistor is a p type MIS transistor, and the second conduction type MIS transistor is an n type MIS transistor, and wherein a work function of the third conducting portion is lower than a work function of the bottom of the second conducting portion obtained before the metal element is diffused.

16. The manufacturing method for a semiconductor device according to claim 11, wherein the structure further comprises a protecting portion provided on the first conducting portion.

17. The manufacturing method for a semiconductor device according to claim 11, wherein forming the structure comprises:
forming an insulating portion having a first groove in the first region and a second groove in the second region;
forming the first gate insulating film and the second gate insulating film in the first groove and the second groove, respectively;
forming the first conducting portion and the second conducting portion on the first gate insulating film and the second gate insulating film, respectively; and
forming a protecting portion on the first conducting portion.

18. The manufacturing method for a semiconductor device according to claim 11, wherein forming the structure comprises:
forming a first structure portion including the first conducting portion and a protecting portion on the first conducting portion and a second structure portion including the second conducting portion and a dummy protecting portion on the second conducting portion;
forming an insulating portion surrounding the first structure portion and the second structure portion; and
removing the dummy protecting portion.

19. The manufacturing method for a semiconductor device according to claim 11, wherein no oxide film is formed on the upper part of the second conducting portion in a plating solution used for the plating method.

20. The manufacturing method for a semiconductor device according to claim 11, further comprising implanting a predetermined element into the second conducting portion before replacing the upper part of the second conducting portion with the third conducting portion.
